(19) United States
(12) Patent Application Publication
(10) Pub. No.: US 2026/0324142 A1
(43) Pub. Date: Oct. 15, 2026

(54) LIGHT EMITTING CHIP, METHOD OF MANUFACTURING LIGHT EMITTING CHIP, DISPLAY PANEL, AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Haokun Li, Beijing (CN); Tingting Zhou, Beijing (CN); Yingtao Wang, Beijing (CN); Jaegeon You, Beijing (CN); Xuefei Sun, Beijing (CN)

(21) Appl. No.: 18/867,762

(22) PCT Filed: Nov. 30, 2023
(86) PCT No.: PCT/CN2023/135441

§ 371 Date: Nov. 20, 2024

(51) Int. Cl. H10H 20/832; H10H 20/01; H10H 20/819; H10H 20/857

(52) U.S. Cl. CPC H10H 20/832; H10H 20/032; H10H 20/0364; H10H 20/819; H10H 20/857

(57) ABSTRACT

A light emitting chip is provided, including: a base substrate; a chip body provided on the base substrate, the chip body includes: a first electrode, a first semiconductor layer, a light emitting layer base, a second semiconductor layer, and a second electrode; and an auxiliary electrode, including a first auxiliary electrode and/or a second auxiliary electrode, where the first auxiliary electrode surrounds at least partially a periphery of a sidewall of the first semiconductor layer, the first auxiliary electrode is insulated from the first semiconductor layer, and the first auxiliary electrode is configured to be connected to a first predetermined voltage; and/or where the second auxiliary electrode surrounds at least partially a periphery of a sidewall of the second semiconductor layer, the second auxiliary electrode is insulated from the second semiconductor layer, and the second auxiliary electrode is configured to be connected to a second predetermined voltage.

### CROSS-REFERENCE TO RELATED APPLICATION

This application is a Section 371 National Stage Application of International Application No. PCT/CN2023/135441, filed on Nov. 30, 2023, entitled “LIGHT EMITTING CHIP, METHOD OF MANUFACTURING LIGHT EMITTING CHIP, DISPLAY PANEL, AND DISPLAY DEVICE”, the content of which is hereby incorporated by reference in its entirety.

### TECHNICAL FIELD

The present disclosure relates to a field of display technology, and in particular to a light emitting chip, a method of manufacturing a light emitting chip, a display panel, and a display device.

### BACKGROUND

Micro Light Emitting Diode (Micro LED) is a new generation of display technology with advantages of self-illumination, high efficiency, high brightness, etc. With a continuous advancement of Augmented Reality (AR) and Virtual Reality (VR) technologies, a size of Micro LED chip is required to be continuously reduced to meet a product requirement. Studies have proved that, in a case of a constant operating current density, an external quantum efficiency of Micro LED may decrease sharply as a chip size is reduced. How to avoid a problem of reduced external quantum efficiency of Micro LED chip while reducing the size of Micro LED chip is one of the topics that R&D personnel of display products are concerned about.

The above information disclosed in this section is just for understanding of the background of technical concepts of the present disclosure. Therefore, the above information may contain information that does not constitute a related art.

### SUMMARY

In an aspect, a light emitting chip is provided, including: a base substrate; a chip body provided on the base substrate, where the chip body includes: a first electrode provided on the base substrate, a first semiconductor layer provided on a side of the first electrode away from the base substrate, a light emitting layer provided on a side of the first semiconductor layer away from the base substrate, a second semiconductor layer provided on a side of the light emitting layer away from the base substrate, and a second electrode provided on a side of the second semiconductor layer away from the base substrate; and an auxiliary electrode, including a first auxiliary electrode and/or a second auxiliary electrode, where the first auxiliary electrode is provided to at least partially surround a periphery of a sidewall of the first semiconductor layer, the first auxiliary electrode is insulated from the first semiconductor layer, and the first auxiliary electrode is configured to be connected to a first predetermined voltage; and/or where the second auxiliary electrode is provided to at least partially surround a periphery of a sidewall of the second semiconductor layer, the second auxiliary electrode is insulated from the second semiconductor layer, and the second auxiliary electrode is configured to be connected to a second predetermined voltage.

According to some exemplary embodiments, the light emitting chip further includes an insulation layer provided on the sidewall of the first semiconductor layer, a sidewall of the light emitting layer and the sidewall of the second semiconductor layer, and the first auxiliary electrode is provided on a surface of the insulation layer away from the first semiconductor layer; and/or at least part of the second auxiliary electrode is provided on a surface of the insulation layer away from the second semiconductor layer.

According to some exemplary embodiments, the first auxiliary electrode is provided to continuously surround a surface of the insulation layer; and/or at least part of the second auxiliary electrode is provided to continuously surround the surface of the insulation layer.

According to some exemplary embodiments, a first surface of the first auxiliary electrode close to the base substrate is aligned with a first surface of the first semiconductor layer close to the base substrate; a second surface of the first auxiliary electrode away from the base substrate is aligned with a second surface of the first semiconductor layer away from the base substrate; and/or a first surface of the second auxiliary electrode close to the base substrate is aligned with a first surface of the second semiconductor layer close to the base substrate, or the first surface of the second auxiliary electrode close to the base substrate is closer to the base substrate than the first surface of the second semiconductor layer close to the base substrate; and a second surface of the second auxiliary electrode away from the base substrate is aligned with a second surface of the second semiconductor layer away from the base substrate.

According to some exemplary embodiments, a material of the first auxiliary electrode is selected from a conductive metal oxide material or a metal material; and/or a material of the second auxiliary electrode is selected from a conductive metal oxide material or a metal material.

According to some exemplary embodiments, the first auxiliary electrode is electrically connected to the first electrode, and the first electrode and the first auxiliary electrode are connected to the same first predetermined voltage.

According to some exemplary embodiments, the second electrode is located in the same layer as the first auxiliary electrode.

According to some exemplary embodiments, the base substrate further includes a first connection terminal, the first auxiliary electrode is electrically connected to the first connection terminal, and the first connection terminal is configured to provide the first predetermined voltage to the first auxiliary electrode.

According to some exemplary embodiments, the base substrate includes at least two first connection terminals respectively located on two sides of the chip body in a first direction, and the first auxiliary electrode is electrically connected to the at least two first connection terminals, respectively.

According to some exemplary embodiments, an orthographic projection of the first electrode on the base substrate falls within an orthographic projection of the first semiconductor layer on the base substrate.

According to some exemplary embodiments, the light emitting chip further includes a first filling layer, the first filling layer covers the insulation layer and the first auxiliary electrode, and a first surface of the first filling layer away from the base substrate is aligned with a second surface of the second semiconductor layer away from the base substrate.

According to some exemplary embodiments, the light emitting chip further includes a second filling layer surrounding a periphery of the chip body, a first surface of the second filling layer away from the base substrate is aligned with a first surface of the second semiconductor layer close to the base substrate, and the second auxiliary electrode extends from a surface of the insulation layer to a first surface of the second filling layer away from the base substrate.

According to some exemplary embodiments, the second auxiliary electrode is electrically connected to the second electrode, and the second electrode and the second auxiliary electrode are connected to the same second predetermined voltage.

According to some exemplary embodiments, the second auxiliary electrode is located in the same layer as the second electrode.

According to some exemplary embodiments, the base substrate further includes a second connection terminal, the second auxiliary electrode is electrically connected to the second connection terminal, and the second connection terminal is configured to provide a second predetermined voltage to the second auxiliary electrode.

According to some exemplary embodiments, the base substrate includes at least two second connection terminals respectively located on two sides of the chip body in a second direction, and the second auxiliary electrode is electrically connected to the at least two second connection terminals, respectively.

According to some exemplary embodiments, the second filling layer includes a via hole exposing at least part of the second connection terminal, and the second auxiliary electrode overlaps with the second connection terminal through the via hole.

According to some exemplary embodiments, in a direction from a center of the chip body to an outside, a distance between a sidewall of the second filling layer close to the chip body and a sidewall of the via hole close to the chip body is greater than a size of the insulation layer.

According to some exemplary embodiments, an orthographic projection of the second electrode on the base substrate falls within an orthographic projection of the second semiconductor layer on the base substrate.

According to some exemplary embodiments, the first semiconductor layer is an N-type semiconductor layer, and the first predetermined voltage is a negative voltage; and/or the second semiconductor layer is a P-type semiconductor layer, and the second predetermined voltage is a positive voltage.

In another aspect, a method of manufacturing a light emitting chip is provided, including: providing a base substrate; forming a chip body on the base substrate, where the chip body includes: a first electrode formed on the base substrate, a first semiconductor layer formed on a side of the first electrode away from the base substrate, a light emitting layer formed on a side of the first semiconductor layer away from the base substrate, a second semiconductor layer formed on a side of the light emitting layer away from the base substrate, and a second electrode formed on a side of the second semiconductor layer away from the base substrate; and forming an auxiliary electrode, where the auxiliary electrode includes a first auxiliary electrode and/or a second auxiliary electrode, where the first auxiliary electrode is provided to at least partially surround a periphery of a sidewall of the first semiconductor layer, the first auxiliary electrode is insulated from the first semiconductor layer, and the first auxiliary electrode is configured to be connected to a first predetermined voltage; and/or where the second auxiliary electrode is provided to at least partially surround a periphery of a sidewall of the second semiconductor layer, the second auxiliary electrode is insulated from the second semiconductor layer, and the second auxiliary electrode is configured to be connected to a second predetermined voltage.

In another aspect, a display panel is provided, including the light emitting chip described above.

In another aspect, a display device is provided, including the display panel described above.

### BRIEF DESCRIPTION OF THE DRAWINGS

The features and advantages of the present disclosure will be more apparent through the detailed descriptions of exemplary embodiments of the present disclosure with reference to the accompanying drawings. In the accompanying drawings:

FIG. 1 shows a distribution diagram of an external quantum efficiency peak of a light emitting chip as a function of a chip size;

FIG. 2 schematically shows a schematic plan view of a light emitting chip according to embodiments of the present disclosure;

FIG. 3 schematically shows a schematic sectional view at position A1-A2 in FIG. 2;

FIG. 4 schematically shows a schematic plan view of a light emitting chip according to embodiments of the present disclosure;

FIG. 5 schematically shows a schematic sectional view at position B1-B2 in FIG. 4;

FIG. 6 schematically shows a schematic plan view of a light emitting chip according to embodiments of the present disclosure;

FIG. 7 schematically shows a schematic sectional view at position C1-C2 in FIG. 6;

FIG. 8 schematically shows a schematic plan view of a light emitting chip according to embodiments of the present disclosure;

FIG. 9 schematically shows a schematic sectional view at position D1-D2 in FIG. 8;

FIG. 10 schematically shows a schematic plan view of a light emitting chip according to embodiments of the present disclosure;

FIG. 11 schematically shows a schematic sectional view at position E1-E2 in FIG. 10;

FIG. 12 schematically shows a schematic plan view of a light emitting chip according to embodiments of the present disclosure;

FIG. 13 schematically shows a schematic sectional view at position F1-F2 in FIG. 12;

FIG. 14 schematically shows a schematic plan view of a light emitting chip according to embodiments of the present disclosure;

FIG. 15 schematically shows a schematic sectional view at position G1-G2 in FIG. 14;

FIG. 16 schematically shows a schematic plan view of a light emitting chip according to embodiments of the present disclosure;

FIG. 17 schematically shows a schematic sectional view at position H1-H2 in FIG. 16;

FIG. 18 shows a luminous intensity testing diagram of a light emitting chip 1 and a light emitting chip 2;

FIG. 19 schematically shows a flowchart of a method of manufacturing a light emitting chip according to embodiments of the present disclosure;

FIG. 20A to FIG. 20F show formation process diagrams of a light emitting chip provided by at least one embodiment of the present disclosure;

FIG. 21A to FIG. 21H show formation process diagrams of a light emitting chip provided by at least one embodiment of the present disclosure;

FIG. 22A to FIG. 22F show formation process diagrams of a light emitting chip provided by at least one embodiment of the present disclosure;

FIG. 23A to FIG. 23H show formation process diagrams of a light emitting chip provided by at least one embodiment of the present disclosure;

FIG. 24A to FIG. 24F show formation process diagrams of a light emitting chip provided by at least one embodiment of the present disclosure;

FIG. 25A to FIG. 25H show formation process diagrams of a light emitting chip provided by at least one embodiment of the present disclosure;

FIG. 26A to FIG. 26H show formation process diagrams of a light emitting chip provided by at least one embodiment of the present disclosure; and

FIG. 27A to FIG. 27H show formation process diagrams of a light emitting chip provided by at least one embodiment of the present disclosure.

It should be noted that, for the purpose of clarity, in the accompanying drawings used to describe the embodiments of the present disclosure, the sizes of layers, structures, or regions may be enlarged or reduced, that is, the accompanying drawings are not drawn to an actual scale.

### DETAILED DESCRIPTION OF EMBODIMENTS

In the following description, for the purpose of explanation, many specific details are set forth to provide comprehensive understanding of various exemplary embodiments. However, it is obvious that various exemplary embodiments may be implemented without these specific details or with one or more equivalent arrangements. In other cases, well-known structures and devices are shown in block diagrams in order to avoid unnecessarily obscuring the various exemplary embodiments. In addition, the various exemplary embodiments may be different, but need not be exclusive. For example, without departing from the inventive concept, a specific shape, configuration and characteristic of an exemplary embodiment may be used or implemented in another exemplary embodiment.

In the accompanying drawings, for the purpose of clarity and/or description, a size and relative size of an element may be enlarged. Accordingly, the size and relative size of each element need not to be limited to those shown in the accompanying drawings. When the exemplary embodiments may be implemented differently, a specific process order may be different from the described order. For example, two successively described processes may be performed substantially simultaneously or in a reverse order. Further, the same reference signs indicate the same elements.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, should be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For the purpose of the present disclosure, “at least one selected from X, Y or Z” and “at least one selected from a group consisting of X, Y and Z” may be interpreted as only X, only Y, only Z, or any combination of two or more of X, Y and Z, such as XYZ, XY, YZ and XZ. As used herein, the term “and/or” includes any and all combinations of one or more of the listed related items.

It should be understood that although the terms “first”, “second”, and so on may be used herein to describe various elements, these elements should not be limited by these terms. These terms are only used to distinguish one element from another one. For example, a first element may be named as a second element without departing from the scope of exemplary embodiments, and similarly, a second element may be named as a first element.

With the development of technology, Micro LED display technology shows a great development momentum. For example, Micro LED display technology has begun to be applied in AR and VR applications. In the Micro LED display technology applied in AR and VR applications, a PPI is generally higher, and a Micro LED chip requires a smaller size.

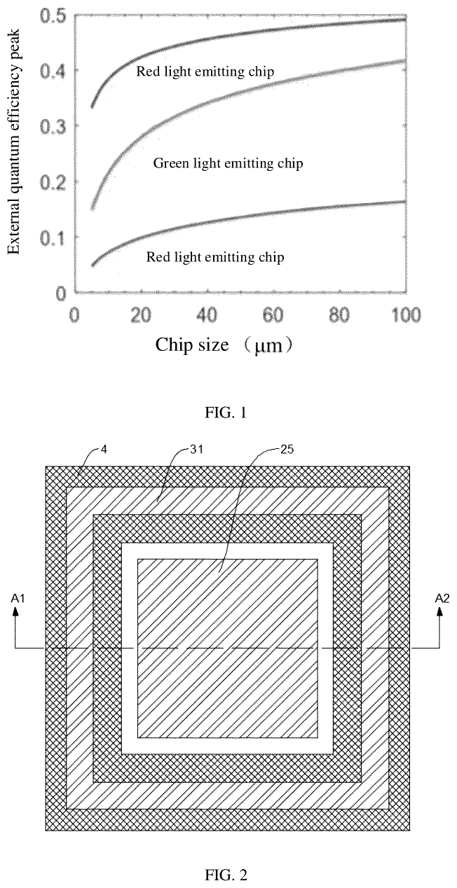

Experiments show that, in a case of a constant operating current density, an external quantum efficiency of a Micro LED chip may decrease sharply as a chip size is reduced. FIG. 1 shows a distribution diagram of an external quantum efficiency peak of a light emitting chip as a function of a chip size. With reference to FIG. 1, an external quantum efficiency peak of a red light emitting chip, an external quantum efficiency peak of a green light emitting chip and an external quantum efficiency peak of a blue light emitting chip all show a significant downward trend as the chip size is reduced.

It should be understood that when photons are incident on a surface of a photosensitive device, some photons may excite a photosensitive material to generate electron-hole pairs, thus forming a current. A ratio of the collected electrons (through internal electron-hole recombination and other processes) to the number of all incident photons is called External Quantum Efficiency (EQE). For a light emitting diode or a light emitting chip, the external quantum efficiency is equal to a ratio of the number of photons emitted in the plane per unit time to the number of the electron-hole pairs injected in the plane per unit time.

The inventors found through studies that a reason for such phenomenon is that, during a chip manufacturing process, a sidewall of the chip formed by an etching process may be inevitably damaged, and a large number of defects may be formed at the sidewall to cause a non-radiative recombination. As the chip size is further reduced, the defects on the sidewall of the chip become more significant, which may lead to a higher proportion of non-radiative recombination. Accordingly, the external quantum efficiency of Micro LED chip decreases sharply as the chip size is reduced.

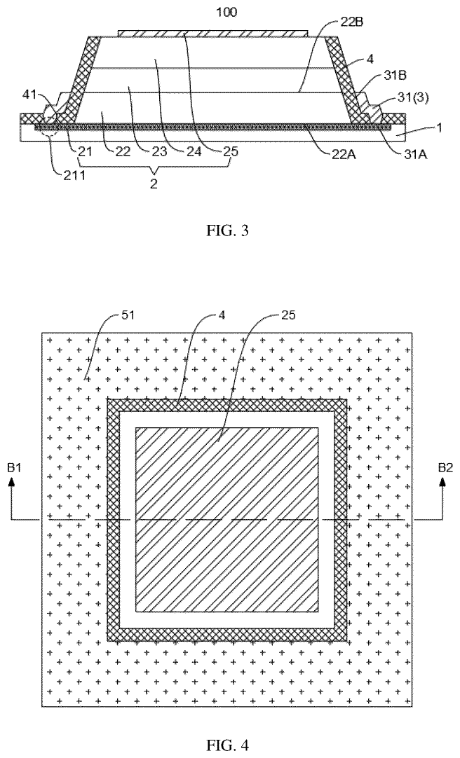

FIG. 2 schematically shows a schematic plan view of a light emitting chip according to embodiments of the present disclosure. FIG. 3 schematically shows a schematic sectional view at position A1-A2 in FIG. 2.

With reference to FIG. 2 and FIG. 3, a light emitting chip 100 may include: a base substrate 1; a chip body 2 provided on the base substrate 1; and an auxiliary electrode 3. The chip body 2 includes a first electrode 21 provided on the base substrate 1, a first semiconductor layer 22 provided on a side of the first electrode 21 away from the base substrate 1, a light emitting layer 23 provided on a side of the first semiconductor layer 22 away from the base substrate 1, a second semiconductor layer 24 provided on a side of the light emitting layer 23 away from the base substrate 1, and a second electrode 25 provided on a side of the second semiconductor layer 24 away from the base substrate 1. The auxiliary electrode 3 includes a first auxiliary electrode 31. The first auxiliary electrode 31 surrounds at least partially a periphery of a sidewall of the first semiconductor layer 22, the first auxiliary electrode 31 is insulated from the first semiconductor layer 22, and the first auxiliary electrode 31 is configured to be connected to a first predetermined voltage.

Here, after being connected to the first predetermined voltage, the first auxiliary electrode 31 surrounding the periphery of the sidewall of the first semiconductor layer 22 may form a horizontal electrical field approximately parallel to the base substrate 1 in a space where the first semiconductor layer 22 is located. Under an action of the electric field, carriers in the first semiconductor layer 22 may move from an edge of the chip body 2 to a center of the chip body 2 to a certain extent, then a probability of Shockley-Read-Hall (SRH) recombination of carriers in a sidewall region of the chip body 2 may be reduced, and more carriers may move and recombine in a central region of the chip body 2, so that a proportion of radiative recombination may be increased, and a higher external quantum efficiency and a higher luminance may be achieved.

It should be noted that SRH recombination is a recombination process mediated by a defect level. When free electrons or free holes encounter a defect level in a material, they may undergo a non-radiative recombination at the defect level, i.e. a conversion to a thermal energy. Such recombination process is considered to be one of the main sources of a non-radiative loss.

For example, the base substrate 1 includes a base plate and a driving circuit provided on the base plate. The driving circuit is electrically connected to the first electrode 21 and the second electrode 25, respectively, and provides a power signal to the first electrode 21 and the second electrode 25, respectively, so as to drive the chip body 2 to emit light. A material of the base plate may include but not be limited to glass, quartz, plastic, silicon, polyimide, and the like.

For example, one of the first electrode 21 and the second electrode 25 is a transparent electrode, and the other is an opaque electrode.

For example, the first electrode 21 is an opaque electrode. A material of the first electrode may be a metal material, which may include, for example, one of more of aluminum (Al), titanium (Ti), molybdenum (Mo), copper (Cu), platinum (Pt), gold (Au), silver (Ag), chromium (Cr), and the like.

For example, the second electrode 25 is a transparent electrode. A material of the second electrode 25 is a conductive metal oxide material, which may include, for example, at least one of indium tin oxide (ITO), indium zinc oxide (IZO), zinc oxide (ZnO), indium oxide (In2O3) or indium gallium oxide (IGO), or a combination thereof.

For example, one of the first semiconductor layer 22 and the second semiconductor layer 24 is a P-type semiconductor layer, and the other is an N-type semiconductor layer. A material of the P-type semiconductor layer may be P-type gallium nitride (GaN), which is denoted as P-GaN. A material of the N-type semiconductor layer may be N-type gallium nitride (GaN), which is denoted as N-GaN.

For example, the first semiconductor layer 22 is an N-type semiconductor layer, and the second semiconductor layer 24 is a P-type semiconductor layer.

For example, the light emitting layer 23 may be a single quantum well (SQW) layer or a multiple quantum well (MQW) layer.

For example, a slope angle formed by the sidewall of the first semiconductor layer 22 and a bottom surface of the first semiconductor layer 22, a slope angle formed by a sidewall of the light emitting layer 23 and the bottom surface of the first semiconductor layer 22, and a slope angle formed by a sidewall of the second semiconductor layer 24 and the bottom surface of the first semiconductor layer 22 range from 70° to 80°.

In some embodiments, still with reference to FIG. 2 and FIG. 3, the light emitting chip 100 further includes an insulation layer 4 provided on the sidewall of the first semiconductor layer, the sidewall of the light emitting layer and the sidewall of the second semiconductor layer 24. The first auxiliary electrode 31 is provided on a surface of the insulation layer 4 away from the first semiconductor layer 22.

Here, the insulation layer 4 may passivate and repair a sidewall of the chip body 2, so as to decrease a probability of SRH recombination in the sidewall region to a certain extent and further improve the external quantum efficiency and the luminance of the light emitting chip 100. Additionally, the first auxiliary electrode 31 is provided on the insulation layer 4, so that the first auxiliary electrode 31 is insulated from the first semiconductor layer 22.

In some embodiments, the insulation layer 4 completely covers the sidewall of the first semiconductor layer 22, the sidewall of the light emitting layer 23 and the sidewall of the second semiconductor layer 24, and the insulation layer 4 has an opening exposing the second semiconductor layer 24.

For example, a material of the insulation layer 4 may include but not be limited to SiNx (silicon nitride), SiOx (silicon oxide) or the like.

In some embodiments, the first auxiliary electrode 31 has a continuous annular structure, and the first auxiliary electrode 31 continuously surrounds a surface of the insulation layer 4.

In some embodiments, the first auxiliary electrode 31 may include a plurality of first auxiliary sub-electrodes, which are arranged at intervals around an outer side of the first semiconductor layer. For example, the first auxiliary electrode 31 may include two first auxiliary sub-electrodes symmetrically arranged on two sides of the first semiconductor layer.

In some embodiments, with reference to FIG. 3, a first surface 31A of the first auxiliary electrode 31 close to the base substrate 1 is aligned with a first surface 22A of the first semiconductor layer 22 close to the base substrate 1, and a second surface 31B of the first auxiliary electrode 31 away from the base substrate 1 is aligned with a second surface 22B of the first semiconductor layer 22 away from the base substrate 1, so as to ensure that an electric field may be formed in a space within a thickness range of the first semiconductor layer 22.

In an actual preparation process, due to an accuracy of the preparation process and other factors, it is difficult for the first surface 31A of the first auxiliary electrode 31 close to the base substrate 1 to be completely aligned with the first surface 22A of the first semiconductor layer 22 close to the base substrate 1, and it is also difficult for the second surface 31B of the first auxiliary electrode 31 away from the base substrate 1 to be completely aligned with the second surface 22B of the first semiconductor layer 22 away from the base substrate 1. However, it should be ensured that more than three-quarters of the sidewall of the first semiconductor layer 22 are surrounded by the first auxiliary electrode 31.

In some embodiments, with reference to FIG. 3, the first auxiliary electrode 31 is electrically connected to the first electrode 21, and the first electrode 21 and the first auxiliary electrode 31 are connected to the same first predetermined voltage. The first predetermined voltage is not only provided to the first auxiliary electrode 31 to form a required electric field, but also serves as a power supply voltage of the first electrode 21 to drive the chip body 2 to emit light. The first auxiliary electrode 31 and the first electrode 21 may be connected to the first predetermined voltage through the same wire, thereby simplifying a structure of the light emitting chip 100.

In some embodiments, the insulation layer 4 extends on the base substrate 1 to cover a surface of the base substrate 1 where the chip body 2 is not provided. The first electrode 21 has a connecting portion 211 extending to an outside of the first semiconductor layer 22. The insulation layer 4 has a hollow structure 41 exposing at least part of the connecting portion 211. The hollow structure 41 exposes at least part of the connecting portion 211, and the first auxiliary electrode 31 overlaps with the connecting portion 211 through the hollow structure 41.

The hollow structure 41 may include one or more via holes arranged at intervals, or the hollow structure 41 may be an annular groove surrounding the first semiconductor layer 22.

In some embodiments, the second electrode 25 is located in the same layer as the first auxiliary electrode 31, that is, the second electrode 25 and the first auxiliary electrode 31 are made of the same material by the same film forming process and the same patterning process. Exemplarily, the material of the second electrode 25 and the first auxiliary electrode 31 is selected from a conductive metal oxide material, which may include, for example, at least one of indium tin oxide (ITO), indium zinc oxide (IZO), zinc oxide (ZnO), indium oxide (In2O3) or indium gallium oxide (IGO), or a combination thereof.

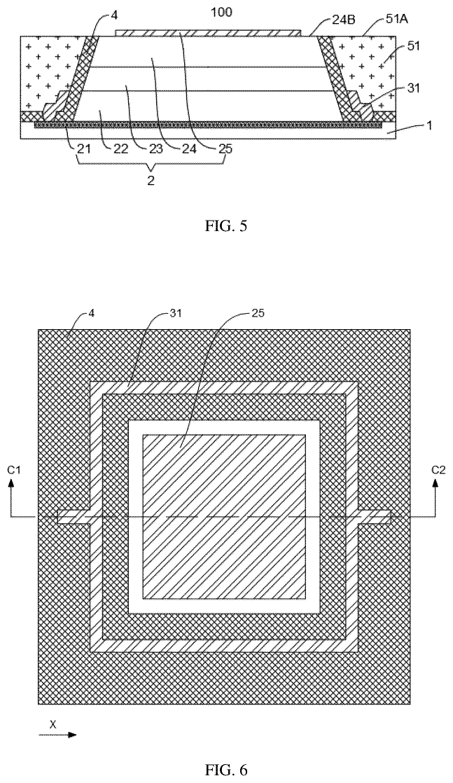

FIG. 4 schematically shows a schematic plan view of a light emitting chip according to embodiments of the present disclosure. FIG. 5 schematically shows a schematic sectional view at position B1-B2 in FIG. 4.

In some embodiments, with reference to FIG. 5, the second electrode 25 is located in a different layer from the first auxiliary electrode 31, that is, the second electrode 25 and the first auxiliary electrode 31 are made by different film forming processes and different patterning processes, and the material of the second electrode 25 may be different from the material of the first auxiliary electrode 31. For example, the material of the first auxiliary electrode 31 may be selected from a metal material. The first auxiliary electrode 31 made of the metal material generally has a high reflectivity, so that the first auxiliary electrode 31 provided on the periphery of the first semiconductor layer 22 may alleviate a light leakage phenomenon of a sidewall to a certain extent.

The material of the first auxiliary electrode 31 is a metal material having a good electrical conductivity, including but not limited to aluminum, copper, tin, or other alloy materials.

In some embodiments, with reference to FIG. 4 and FIG. 5, the light emitting chip 100 further includes a first filling layer 51. The first filling layer 51 covers the insulation layer 4 and the first auxiliary electrode 31, and a first surface 51A of the first filling layer 51 away from the base substrate 1 is aligned with a second surface 24B of the second semiconductor layer 24 away from the base substrate 1.

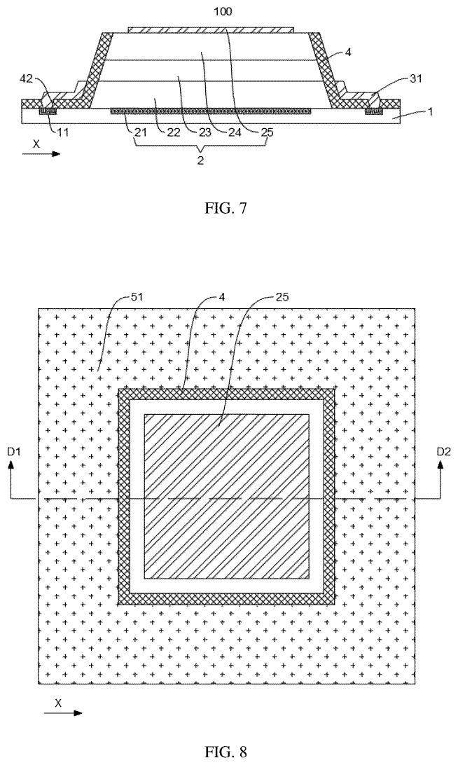

FIG. 6 schematically shows a schematic plan view of a light emitting chip according to embodiments of the present disclosure. FIG. 7 schematically shows a schematic sectional view at position C1-C2 in FIG. 6.

In some embodiments, with reference to FIG. 6 and FIG. 7, the base substrate 1 further includes a first connection terminal 11, the first auxiliary electrode 31 is electrically connected to the first connection terminal 11, and the first connection terminal 11 is configured to provide the first predetermined voltage to the first auxiliary electrode 31. In such structure, the first auxiliary electrode 31 and the first electrode 21 are independently connected to a voltage signal, and the first predetermined voltage connected to the first auxiliary electrode 31 may be adjusted and controlled according to a working state of the light emitting chip.

In some embodiments, the base substrate 1 includes at least two first connection terminals 11 respectively located on two sides of the chip body in a first direction X, and the first auxiliary electrode 31 is electrically connected to the first connection terminals 11, respectively.

As shown in FIG. 6 and FIG. 7, the base substrate 1 includes two first connection terminals 11 respectively located on two sides of the chip body in the first direction X. The insulation layer 4 includes a first via hole 42 exposing at least part of the first connection terminal 11. The first auxiliary electrode 31 continuously surrounds an outside of the insulation layer 4, extends toward the first connection terminal 11, and overlaps with the first connection terminal 11 through the first via hole 42 to achieve an electrical connection.

In some embodiments, with reference to FIG. 7, an orthographic projection of the first electrode 21 on the base substrate 1 falls within an orthographic projection of the first semiconductor layer 22 on the base substrate 1. Such arrangement facilitates a transmission and a recombination of electrons and holes in the central region of the chip body, which may reduce occurrence of non-radiative recombination at the sidewall defect to a certain extent.

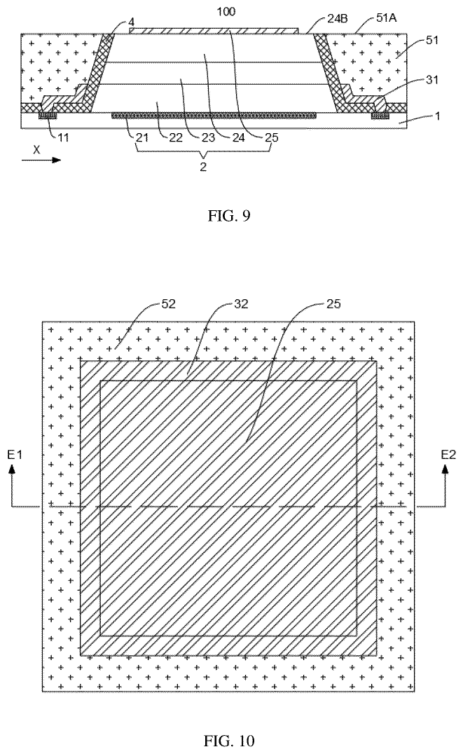

FIG. 8 schematically shows a schematic plan view of a light emitting chip according to embodiments of the present disclosure. FIG. 9 schematically shows a schematic sectional view at position D1-D2 in FIG. 8.

In some embodiments, with reference to FIG. 8 and FIG. 9, the first auxiliary electrode 31 is electrically connected to the first connection terminal 11, and the first connection terminal 11 is configured to provide the first predetermined voltage to the first auxiliary electrode 31. The second auxiliary electrode 25 is located in a different layer from the first auxiliary electrode 31. The light emitting chip further includes a first filling layer 51, the first filling layer 51 covers the insulation layer 4 and the first auxiliary electrode 31, and a first surface 51A of the first filling layer 51 away from the base substrate 1 is aligned with a second surface 24B of the second semiconductor layer 24 away from the base substrate 1.

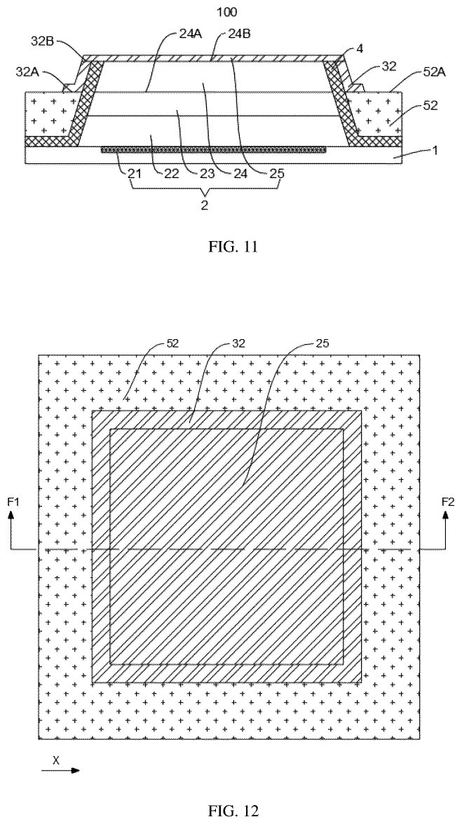

FIG. 10 schematically shows a schematic plan view of a light emitting chip according to embodiments of the present disclosure. FIG. 11 schematically shows a schematic sectional view at position E1-E2 in FIG. 10.

In some embodiments, with reference to FIG. 10 and FIG. 11, the light emitting chip further includes a second filling layer 52 surrounding a periphery of the chip body. A first surface 52A of the second filling layer 52 away from the base substrate 1 is aligned with a first surface 24A of the second semiconductor layer 24 close to the base substrate 1. The second auxiliary electrode 32 extends from a surface of the insulation layer 4 to the first surface 52A of the second filling layer 52 away from the base substrate 1.

Here, after being connected to a second predetermined voltage, the second auxiliary electrode 32 surrounding the periphery of the sidewall of the second semiconductor layer 24 may form a horizontal electrical field approximately parallel to the base substrate 1 in a space where the second semiconductor layer 24 is located. Under an action of the electric field, carriers in the second semiconductor layer 24 may move from an edge of the chip body 2 to a center of the chip body 2 to a certain extent, then a probability of Shockley-Read-Hall recombination of carriers in a sidewall region of the chip body 2 may be reduced, and more carriers may move and recombine in a central region of the chip body 2, so that a proportion of radiative recombination may be increased, and a higher external quantum efficiency and a higher luminance may be achieved.

In some embodiments, the second auxiliary electrode 32 has a continuous annular structure, and at least part of the second auxiliary electrode 32 continuously surrounds a surface of the insulation layer 4. As exemplarily shown in FIG. 10 and FIG. 11, the second auxiliary electrode 32 continuously surrounds the surface of the insulation layer 4.

In some embodiments, the second auxiliary electrode 32 may include a plurality of second auxiliary sub-electrodes, which are arranged at intervals around an outer side of the second semiconductor layer. For example, the second auxiliary electrode 32 may include two second auxiliary sub-electrodes symmetrically arranged on two sides of the second semiconductor layer.

In some embodiments, with reference to FIG. 11, a first surface 32A of the second auxiliary electrode 32 close to the base substrate 1 is aligned with a first surface 24A of the second semiconductor layer 24 close to the base substrate 1, and a second surface 32B of the second auxiliary electrode 32 away from the base substrate 1 is aligned with a second surface 24B of the second semiconductor layer 24 away from the base substrate 1, so as to ensure that an electric field may be formed in a space within a thickness range of the second semiconductor layer 24.

In an actual preparation process, due to an accuracy of the preparation process and other factors, it is difficult for the first surface 32A of the second auxiliary electrode 32 close to the base substrate 1 to be completely aligned with the first surface 24A of the second semiconductor layer 24 close to the base substrate 1, and it is also difficult for the second surface 32B of the second auxiliary electrode 32 away from the base substrate 1 to be completely aligned with the second surface 24B of the second semiconductor layer 24 away from the base substrate 1. However, it should be ensured that more than three-quarters of the sidewall of the second semiconductor layer 24 are surrounded by the second auxiliary electrode 32.

In some embodiments, the second auxiliary electrode 32 is electrically connected to the second electrode 25, and the second electrode 25 and the second auxiliary electrode 32 are connected to the same second predetermined voltage. The second predetermined voltage is not only provided to the second auxiliary electrode 32 to form a required electric field, but also serves as a power supply voltage of the second electrode 25 to drive the chip body 2 to emit light. The second auxiliary electrode 32 and the second electrode 25 may be connected to the second predetermined voltage through the same wire, thereby simplifying a structure of the light emitting chip 100.

In some embodiments, the second electrode 25 has a structure extending toward the second auxiliary electrode 32 and overlapping with the second auxiliary electrode 32, so that the second electrode 25 is electrically connected to the second auxiliary electrode 32. For example, with reference to FIG. 10 and FIG. 11, the second auxiliary electrode 32 continuously surrounds an outside of the insulation layer 4, the second electrode 25 extends outward as a whole, and an outer edge of the second electrode 25 is connected to an upper edge of the second auxiliary electrode.

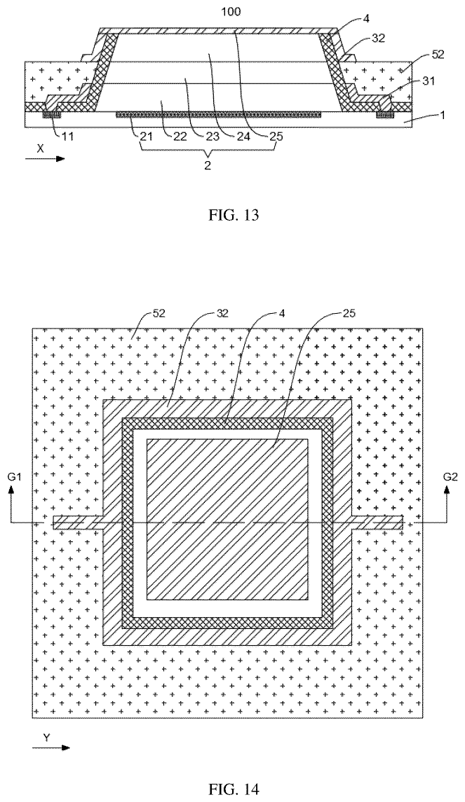

FIG. 12 schematically shows a schematic plan view of a light emitting chip according to embodiments of the present disclosure. FIG. 13 schematically shows a schematic sectional view at position F1-F2 in FIG. 12.

In some embodiments, with reference to FIG. 12 and FIG. 13, the light emitting chip is provided with both the first auxiliary electrode 31 and the second auxiliary electrode 32. The first auxiliary electrode 31 is electrically connected to the first connection terminal 11. The second filling layer 52 surrounds an outside of the insulation layer 4 and covers the first auxiliary electrode 31. The second auxiliary electrode 32 is provided on the second filling layer 52 and is electrically connected to the second electrode.

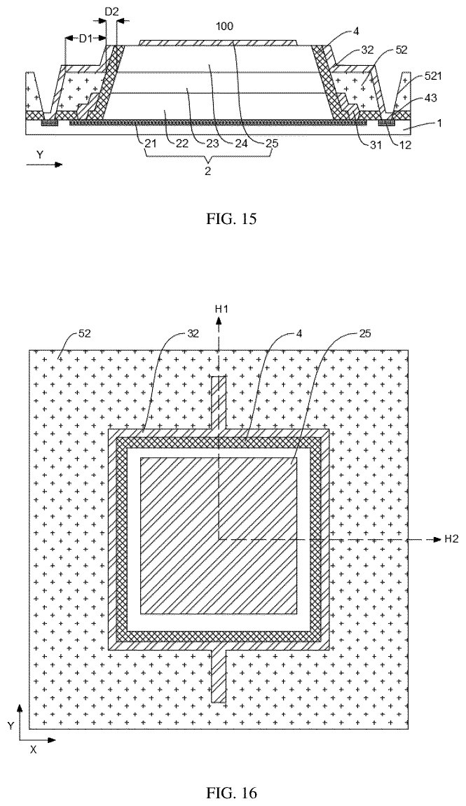

FIG. 14 schematically shows a schematic plan view of a light emitting chip according to embodiments of the present disclosure. FIG. 15 schematically shows a schematic sectional view at position G1-G2 in FIG. 14.

In some embodiments, with reference to FIG. 14 and FIG. 15, the base substrate 1 further includes a second connection terminal 12, the second auxiliary electrode 32 is electrically connected to the second connection terminal 12, and the second connection terminal 12 is configured to provide the second predetermined voltage to the second auxiliary electrode 32. In such structure, the second auxiliary electrode 32 and the second electrode 25 are independently connected to a voltage signal, and the second predetermined voltage connected to the second auxiliary electrode 32 may be adjusted and controlled according to a working state of the light emitting chip.

In some embodiments, the base substrate 1 includes at least two second connection terminals 12 respectively located on two sides of the chip body in a second direction Y, and the second auxiliary electrode 32 is electrically connected to the second connection terminals 12, respectively. For example, the base substrate 1 may include two second connection terminals 12 respectively located on two sides of the chip body in the second direction Y, and the second auxiliary electrode 32 is electrically connected to the two second connection terminals 12, respectively.

In some embodiments, with reference to FIG. 15, the insulation layer 4 includes a second via hole 43 exposing at least part of the second connection terminal 12. The second filling layer 52 has a third via hole 521, which is connected to the second via hole 43 and exposes at least part of the second connection terminal 12. The second auxiliary electrode 32 extends from an upper surface of the second filling layer 52 to the second connection terminal 12 through a hole wall of the third via hole 521 and the second via hole 43, so as to overlap with the second connection terminal 12 to achieve an electrical connection.

In some embodiments, with reference to FIG. 15, in a direction from a center of the chip body to an outside, a distance D1 between a sidewall of the second filling layer 52 close to the chip body 2 and a sidewall of the third via hole 521 close to the chip body 2 is greater than a size D2 of the insulation layer 4, so that the part of the second auxiliary electrode 52 located in the third via hole 521 is as far away as possible from the first auxiliary electrode 31 and the first electrode 21 to avoid an interference between the second auxiliary electrode 52 and the first auxiliary electrode 31 or between the second auxiliary electrode 52 and the first electrode 21.

In some embodiments, a material of the second filling layer 52 is selected from an organic insulation adhesive material. In practice, it is possible to select an organic insulation adhesive material having a relatively large dielectric constant. For example, it is possible to select an organic insulation adhesive material having a larger dielectric constant than the material of the insulation layer 4.

In some embodiments, with reference to FIG. 15, the light emitting chip is provided with both the first auxiliary electrode 31 and the second auxiliary electrode 32. The first auxiliary electrode 31 is electrically connected to the first electrode 21, and the second auxiliary electrode 32 is electrically connected to the second connection terminal 12.

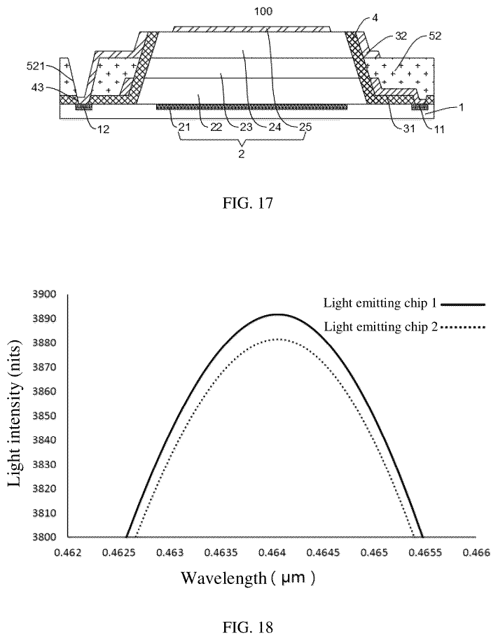

FIG. 16 schematically shows a schematic plan view of a light emitting chip according to embodiments of the present disclosure. FIG. 17 schematically shows a schematic sectional view at position H1-H2 in FIG. 16

In some embodiments, with reference to FIG. 16 and FIG. 17, the light emitting chip is provided with both the first auxiliary electrode 31 and the second auxiliary electrode 32. The first auxiliary electrode 31 is electrically connected to the first connection terminal 11, and the second auxiliary electrode 32 is electrically connected to the second connection terminal 12.

In some embodiments, the base substrate 1 includes two first connection terminals 11 and two second connection terminals 12. The two first connection terminals 11 are respectively located on two sides of the chip body 2 in the first direction X, and the two second connection terminals 12 are respectively located on two sides of the chip body 2 in the second direction Y. The first auxiliary electrode 31 is electrically connected to the first connection terminals 11, and the second auxiliary electrode 32 is electrically connected to the second connection terminals 12.

In some embodiments, the first direction X is perpendicular to the second direction Y.

In some embodiments, the second auxiliary electrode 32 is located in the same layer as the second electrode 25, that is, the second electrode 25 and the second auxiliary electrode 32 are made by the same film forming process and the same patterning process, and the second electrode 25 and the second auxiliary electrode 32 are made of the same material. Exemplarily, the material of the second electrode 25 and the second auxiliary electrode 32 is selected from a conductive metal oxide material, which may include, for example, at least one of indium tin oxide (ITO), indium zinc oxide (IZO), zinc oxide (ZnO), indium oxide (In2O3) or indium gallium oxide (IGO), or a combination thereof.

In some embodiments, the second auxiliary electrode 32 is located in a different layer from the second electrode 25, that is, the second electrode 25 and the second auxiliary electrode 32 are made by different film forming processes and different patterning processes, and the material of the second auxiliary electrode 32 and the material of the second electrode 25 may be different. For example, the material of the second auxiliary electrode 32 may be selected from a metal material. The second auxiliary electrode 32 made of the metal material generally has a high reflectivity, so that the second auxiliary electrode 32 provided on the periphery of the second semiconductor layer 24 may alleviate a light leakage phenomenon of a sidewall to a certain extent.

The material of the second auxiliary electrode 32 is a metal material having a good electrical conductivity, which may include, for example, one or more of aluminum (Al), titanium (Ti), molybdenum (Mo), copper (Cu), platinum (Pt), gold (Au), silver (Ag), chromium (Cr), and other materials.

In some embodiments, with reference to FIG. 14 to FIG. 17, an orthographic projection of the second electrode 25 on the base substrate 1 falls within an orthographic projection of the second semiconductor layer 24 on the base substrate 1. Such arrangement facilitates a transmission and a recombination of electrons and holes in the central region of the chip body, which may reduce occurrence of non-radiative recombination at the sidewall defect to a certain extent.

In some embodiments, the first semiconductor layer 22 is an N-type semiconductor layer, in which the majority carriers are electrons. The first predetermined voltage may be set to a negative voltage to form a horizontal electric field directed from a center of the first semiconductor layer 22 to an edge of the first semiconductor layer 22, thereby driving the electrons in the first semiconductor layer 22 to move from the edge of the first semiconductor layer 22 to the center of the first semiconductor layer 22.

The second semiconductor layer is a P-type semiconductor layer, in which the majority carriers are holes. The second predetermined voltage may be set to a positive voltage to form a horizontal electric field directed from an edge of the second semiconductor layer 24 to a center of the second semiconductor layer 24, thereby driving the holes in the second semiconductor layer 24 to move from the edge of the second semiconductor layer 24 to the center of the second semiconductor layer 24.

Taking the structure shown in FIG. 10 and FIG. 11 as an example, a light emitting chip 1 may be manufactured. Taking the structure shown in FIG. 10 and FIG. 11 as an example, a light emitting chip 2 may be manufactured, which differs from the light emitting chip 1 only in that no second auxiliary electrode is provided on the periphery of the second semiconductor layer.

A luminous intensity test may be performed on the manufactured light emitting chip 1 and light emitting chip 2. During the test, the second auxiliary electrode in the light emitting chip 1 is connected to a voltage of 3V. FIG. 18 shows a luminous intensity testing diagram of the light emitting chip 1 and the light emitting chip 2. With reference to FIG. 18, according to a test result, the luminous intensity of the light emitting chip 1 is significantly improved compared with that of the light emitting chip 2. Thus, it may be proved that providing the second auxiliary electrode on the periphery of the second semiconductor layer may effectively improve the luminance of the light emitting chip.

Similarly, providing the first auxiliary electrode on the periphery of the first semiconductor layer may effectively improve the luminance of the light emitting chip.

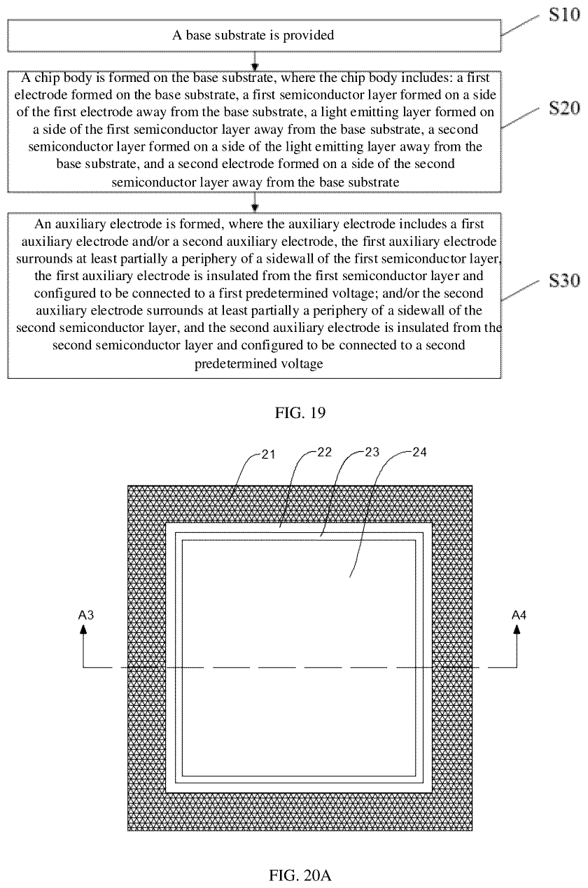

The embodiments of the present disclosure further provide a method of manufacturing a light emitting chip. FIG. 19 schematically shows a flowchart of a method of manufacturing a light emitting chip according to embodiments of the present disclosure. As shown in FIG. 19, the method includes step S10 to step S30 as follows.

In step S10, a base substrate is provided.

In step S20, a chip body is formed on the base substrate, where the chip body includes: a first electrode formed on the base substrate, a first semiconductor layer formed on a side of the first electrode away from the base substrate, a light emitting layer formed on a side of the first semiconductor layer away from the base substrate, a second semiconductor layer formed on a side of the light emitting layer away from the base substrate, and a second electrode formed on a side of the second semiconductor layer away from the base substrate.

In step S30, an auxiliary electrode is formed, where the auxiliary electrode includes a first auxiliary electrode and/or a second auxiliary electrode, the first auxiliary electrode surrounds at least partially a periphery of a sidewall of the first semiconductor layer, the first auxiliary electrode is insulated from the first semiconductor layer and configured to be connected to a first predetermined voltage; and/or the second auxiliary electrode surrounds at least partially a periphery of a sidewall of the second semiconductor layer, and the second auxiliary electrode is insulated from the second semiconductor layer and configured to be connected to a second predetermined voltage.

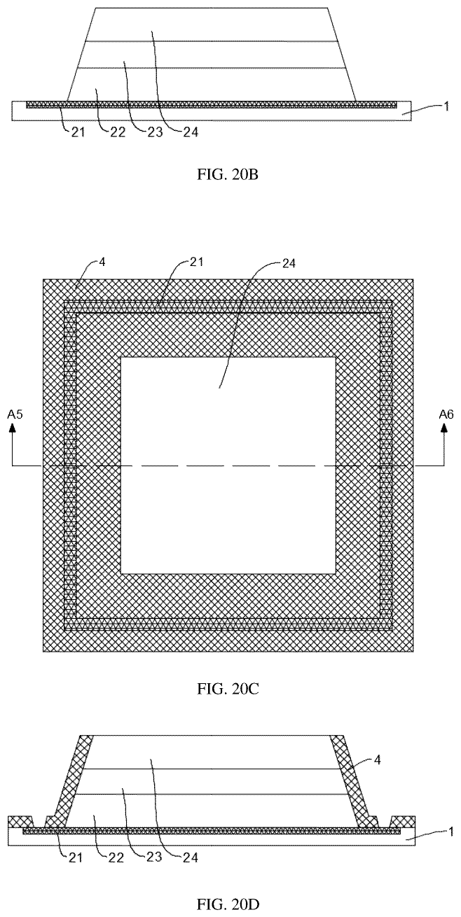

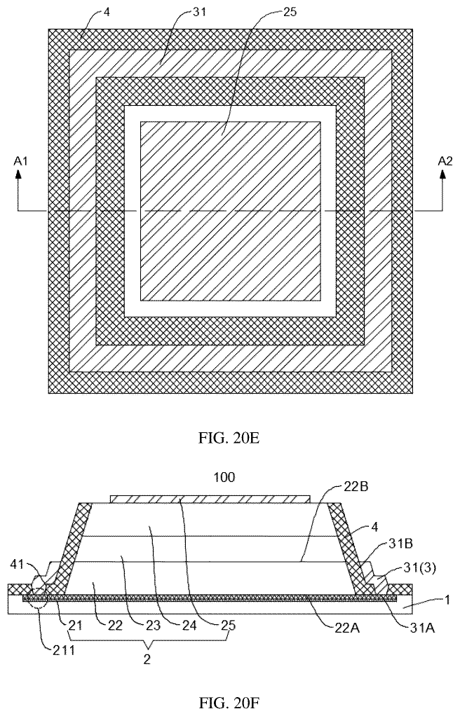

FIG. 20A to FIG. 20F show formation process diagrams of a light emitting chip provided by at least one embodiment of the present disclosure.

As shown in FIG. 20A and the schematic sectional view at position A3-A4 of FIG. 20A shown in FIG. 20B, a base substrate 1 is provided, and the base substrate 1 includes a first electrode 21. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

For example, the base substrate 1 includes a base plate and a driving circuit provided on the base plate, and the first electrode 21 is located in the driving circuit.

For example, the first electrode 21 is an opaque electrode, and a material of the first electrode 21 may include, for example, one or more of aluminum (Al), titanium (Ti), molybdenum (Mo), copper (Cu), platinum (Pt), gold (Au), silver (Ag), chromium (Cr), and the like.

For example, the first semiconductor layer 22, the light emitting layer 23 and the second semiconductor layer 24 arranged in a stack may be specifically obtained by the following steps. A suitable base plate is selected; a first semiconductor film layer, a light-emitting-layer film layer and a second semiconductor film layer are sequentially deposited on the base plate; the first semiconductor film layer, the light-emitting-layer film layer and the second semiconductor film layer are etched under a mask to obtain a first semiconductor layer 22, a light emitting layer 23 and a second semiconductor layer 24 with a predetermined shape; and finally the first semiconductor layer 22, the light emitting layer 23 and the second semiconductor layer 24 formed in a stack are peeled off from the base substrate.

Generally, a slope angle formed by a sidewall of the first semiconductor layer 22 obtained by etching and a bottom surface of the first semiconductor layer 22, a slope angle formed by a sidewall of the light emitting layer 23 obtained by etching and the bottom surface of the first semiconductor layer 22, and a slope angle formed by a sidewall of the second semiconductor layer 24 obtained by etching and the bottom surface of the first semiconductor layer 22 range from 70° to 80°.

For example, the base plate may be a sapphire base plate or a silicon carbide base plate.

For example, the first semiconductor layer 22 is an N-type semiconductor layer, and the second semiconductor layer 24 is a P-type semiconductor layer. A material of the P-type semiconductor layer may be P-type gallium nitride (GaN), which is denoted as P-GaN. A material of the N-type semiconductor layer may be N-type gallium nitride (GaN), which is denoted as N-GaN.

For example, the light emitting layer 23 may be a single quantum well (SQW) layer or a multiple quantum well (MQW) layer.

As shown in FIG. 20C and the schematic sectional view at position A5-A6 of FIG. 20C shown in FIG. 20D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24. Furthermore, the insulation layer 4 has a hollow structure 41 exposing at least part of the first electrode 21.

For example, with reference to FIG. 20C, the hollow structure 41 is an annular groove, and a part of the first electrode 21 exposed by the hollow structure 41 is also annular.

For example, a material of the insulation layer 4 may include, for example, at least one of silicon nitride or silicon oxide.

As shown in FIG. 20E and the schematic sectional view at position A1-A2 of FIG. 20E shown in FIG. 20F, a conductive film layer is formed by deposition, and the conductive film layer is patterned to obtain a second electrode 25 and a first auxiliary electrode 31. The second electrode 25 is located on a side of the second semiconductor layer 24 away from the base substrate 1, and an orthographic projection of the second electrode 25 on the base substrate 1 falls within an orthographic projection of the second semiconductor layer 24 on the base substrate 1. The first auxiliary electrode 31 is located on a side of the insulation layer 4 away from the first semiconductor layer 22, and the first auxiliary electrode 31 overlaps with the first electrode 21 through the hollow structure of the insulation layer 4.

For example, the second electrode 25 is a transparent electrode. A material of the second electrode 25 and a material the first auxiliary electrode 31 may include, for example, at least one of indium tin oxide (ITO), indium zinc oxide (IZO), zinc oxide (ZnO), indium oxide (In2O3) or indium gallium oxide (IGO), or a combination thereof.

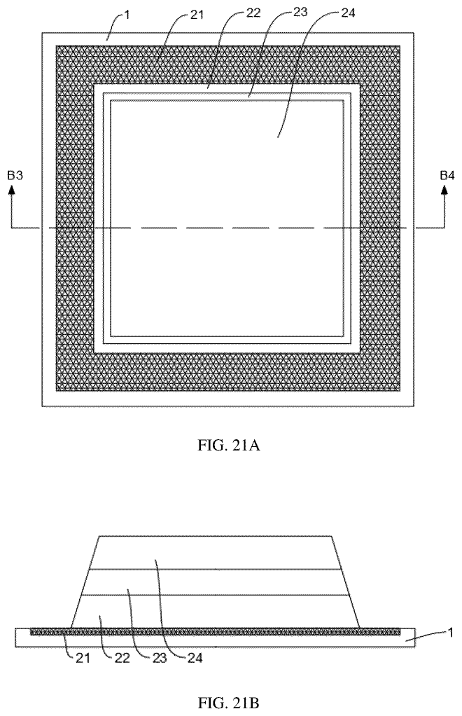

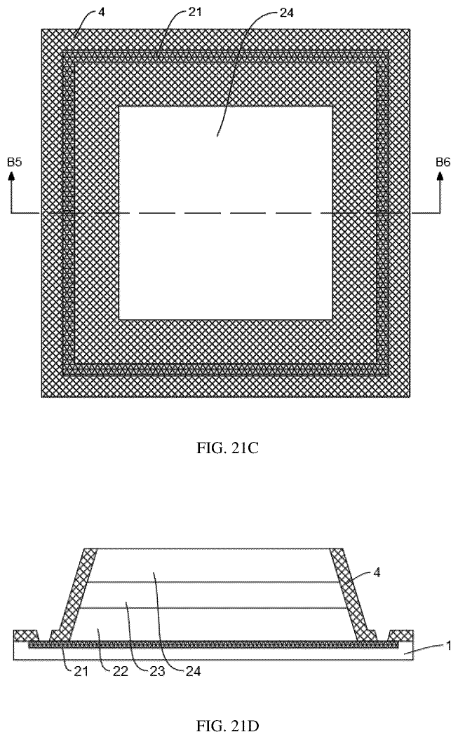

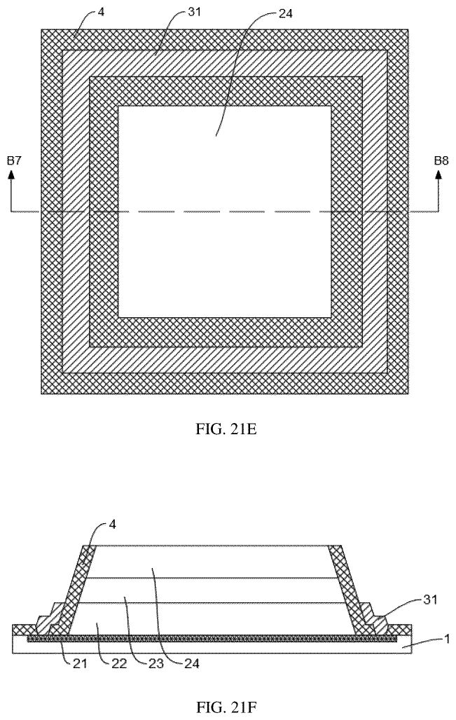

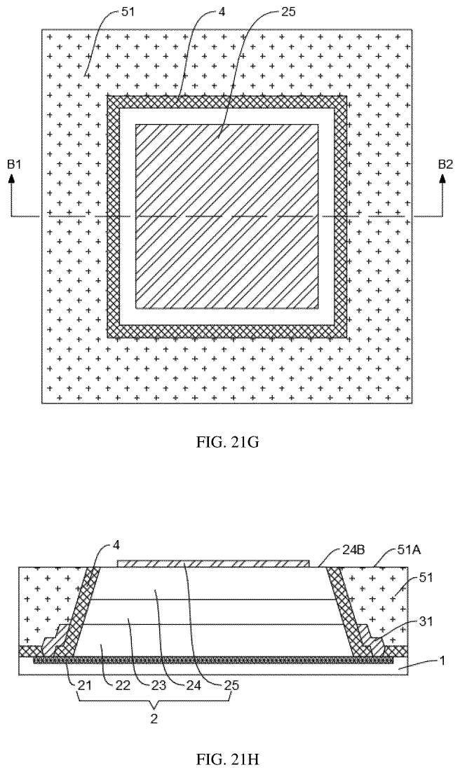

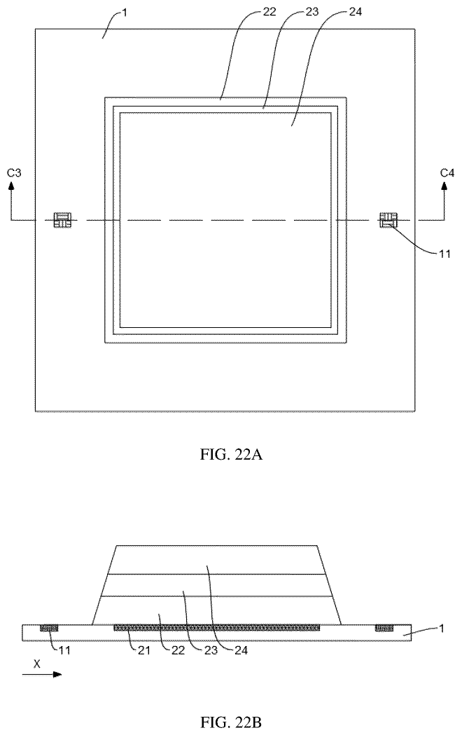

FIG. 21A to FIG. 21H show formation process diagrams of a light emitting chip provided by at least one embodiment of the present disclosure.

As shown in FIG. 21A and the schematic sectional view at position B3-B4 of FIG. 21A shown in FIG. 21B, a base substrate 1 is provided, and the base substrate 1 includes a first electrode 21. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

As shown in FIG. 21C and the schematic sectional view at position B5-B6 of FIG. 21C shown in FIG. 21D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24. Furthermore, the insulation layer 4 has a hollow structure 41 that exposes at least part of the first electrode 21.

As shown in FIG. 21E and the schematic sectional view at position B7-B8 of FIG. 21E shown in FIG. 21F, a first conductive film layer is formed by deposition, and the first conductive film layer is patterned to obtain a first auxiliary electrode 31. The first auxiliary electrode 31 is located on a side of the insulation layer 4 away from the first semiconductor layer 22, and the first auxiliary electrode 31 overlaps with the first electrode 21 through the hollow structure of the insulation layer 4.

For example, a material of the first auxiliary electrode 31 may include, for example, at least one of indium tin oxide (ITO), indium zinc oxide (IZO), zinc oxide (ZnO), indium oxide (In2O3) or indium gallium oxide (IGO), or a combination thereof.

As shown in FIG. 21G and the schematic sectional view at position B1-B2 of FIG. 21G shown in FIG. 21H, an organic insulation adhesive layer is formed, and the organic insulation adhesive layer is patterned to obtain a first filling layer 51. The first filling layer 51 covers the insulation layer 4 and the first auxiliary electrode 31, and a first surface 51A of the first filling layer 51 away from the base substrate 1 is aligned with a second surface 24B of the second semiconductor layer 24 away from the base substrate 1.

A second conductive film layer is then formed by deposition, and the second conductive film layer is patterned to obtain a second electrode 25. The second electrode 25 is located on a side of the second semiconductor layer 24 away from the base substrate 1, and an orthographic projection of the second electrode 25 on the base substrate 1 falls within an orthographic projection of the second semiconductor layer 24 on the base substrate 1.

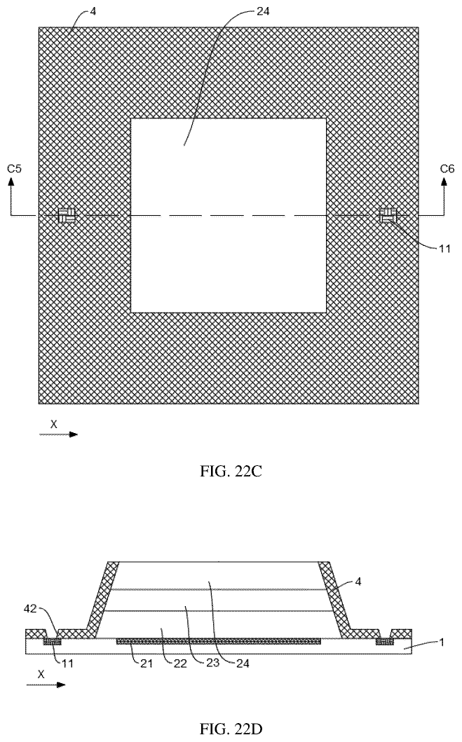

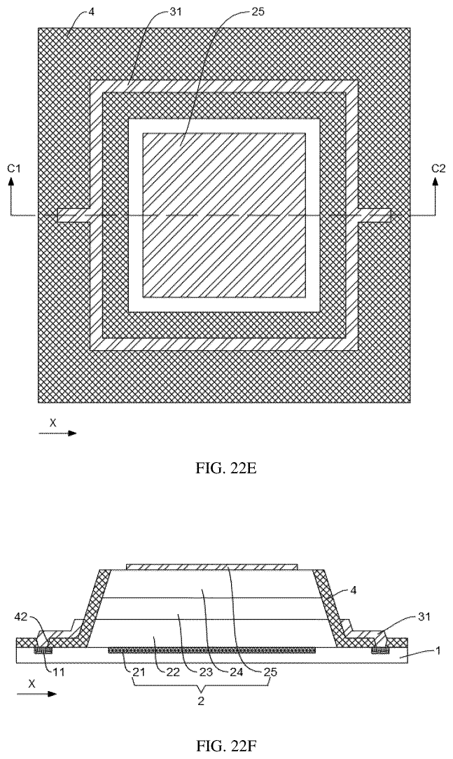

FIG. 22A to FIG. 22F show formation process diagrams of a light emitting chip provided by at least one embodiment of the present disclosure.

As shown in FIG. 22A and the schematic sectional view at position C3-C4 of FIG. 22A shown in FIG. 22B, a base substrate 1 is provided, and the base substrate 1 includes a first electrode 21 and a first connection terminal 11. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

For example, the base substrate 1 includes a base plate and a driving circuit provided on the base plate, and the first electrode 21 and the first connection terminal 11 are located in the driving circuit.

For example, the base substrate 1 includes two connection terminals 11 respectively located on two sides of the first semiconductor layer 22 in the first direction X.

As shown in FIG. 22C and the schematic sectional view at position C5-C6 of FIG. 22C shown in FIG. 22D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24. Furthermore, the insulation layer 4 has a first via hole 42 exposing at least part of the first connection terminal 11.

As shown in FIG. 22E and the schematic sectional view at position C1-C2 of FIG. 22E shown in FIG. 22F, a conductive film layer is formed by deposition, and the conductive film layer is patterned to obtain a second electrode 25 and a first auxiliary electrode 31. The second electrode 25 is located on a side of the second semiconductor layer 24 away from the base substrate 1, and an orthographic projection of the second electrode 25 on the base substrate 1 falls within the orthographic projection of the second semiconductor layer 24 on the base substrate 1. The first auxiliary electrode 31 is located on a side of the insulation layer 4 away from the first semiconductor layer 22, and the first auxiliary electrode 31 overlaps with the first connection terminal 11 through the first via hole 42 of the insulation layer 4.

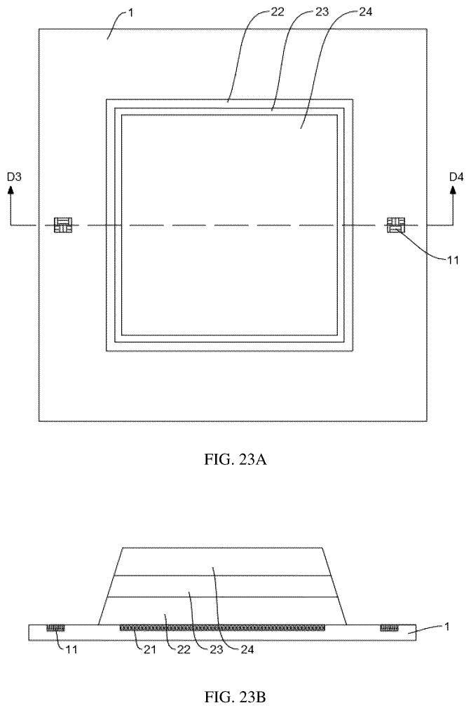

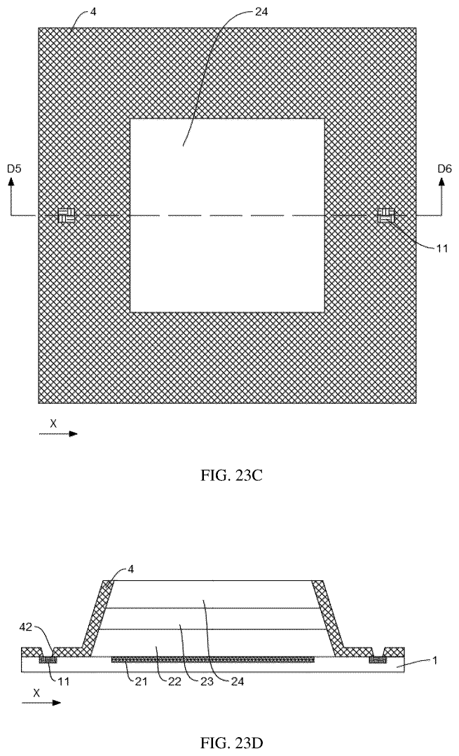

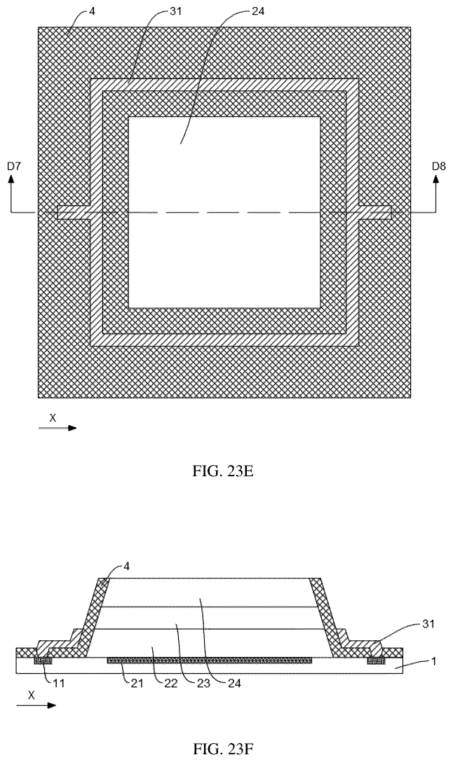

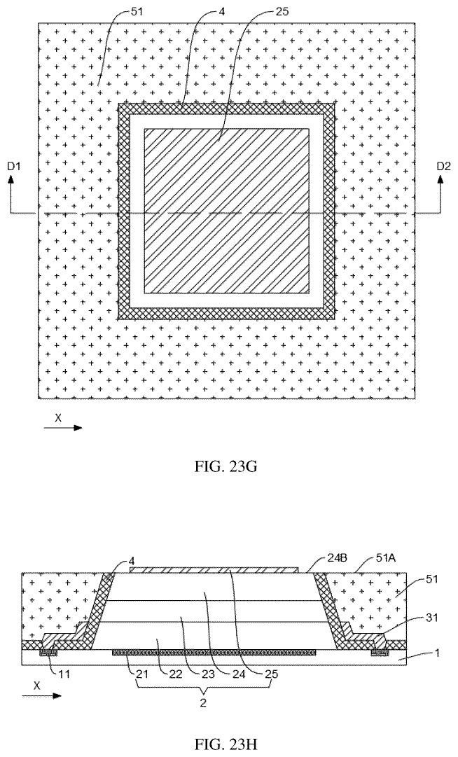

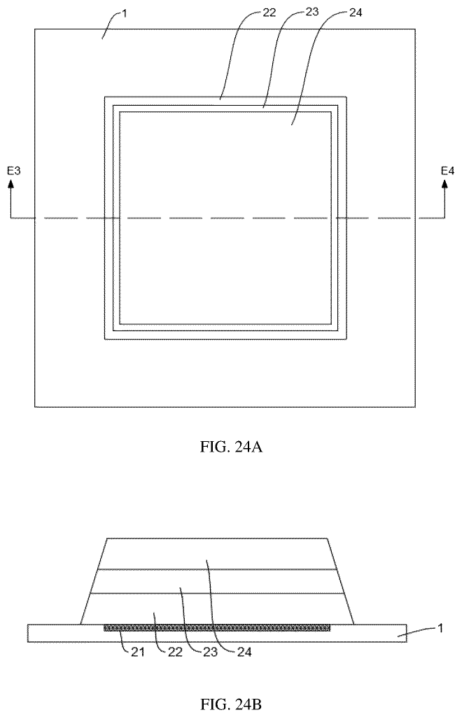

FIG. 23A to FIG. 23H show formation process diagrams of a light emitting chip provided by at least one embodiment of the present disclosure.

As shown in FIG. 23A and the schematic sectional view at position D3-D4 of FIG. 23A shown in FIG. 23B, a base substrate 1 is provided, and the base substrate 1 includes a first electrode 21 and a first connection terminal 11. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

As shown in FIG. 23C and the schematic sectional view at position D5-D6 of FIG. 23C shown in FIG. 23D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24. Furthermore, the insulation layer 4 has a first via hole 42 exposing at least part of the first connection terminal 11.

As shown in FIG. 23E and the schematic sectional view at position D7-D8 of FIG. 23E shown in FIG. 23F, a first conductive film layer is formed by deposition, and the first conductive film layer is patterned to obtain a first auxiliary electrode 31. The first auxiliary electrode 31 is located on a side of the insulation layer 4 away from the first semiconductor layer 22, and the first auxiliary electrode 31 overlaps with the first connection terminal 11 through the first via hole 42 of the insulation layer 4.

As shown in FIG. 23G and the schematic sectional view at position D1-D2 of FIG. 23G shown in FIG. 23H, an organic insulation adhesive layer is formed, and the organic insulation adhesive layer is patterned to obtain a first filling layer 51. The first filling layer 51 covers the insulation layer 4 and the first auxiliary electrode 31, and a first surface 51A of the first filling layer 51 away from the base substrate 1 is aligned with a second surface 24B of the second semiconductor layer 24 away from the base substrate 1.

A second conductive film layer is then formed by deposition, and the second conductive film layer is patterned to obtain a second electrode 25. The second electrode 25 is located on a side of the second semiconductor layer 24 away from the base substrate 1, and an orthographic projection of the second electrode 25 on the base substrate 1 falls within an orthographic projection of the second semiconductor layer 24 on the base substrate 1.

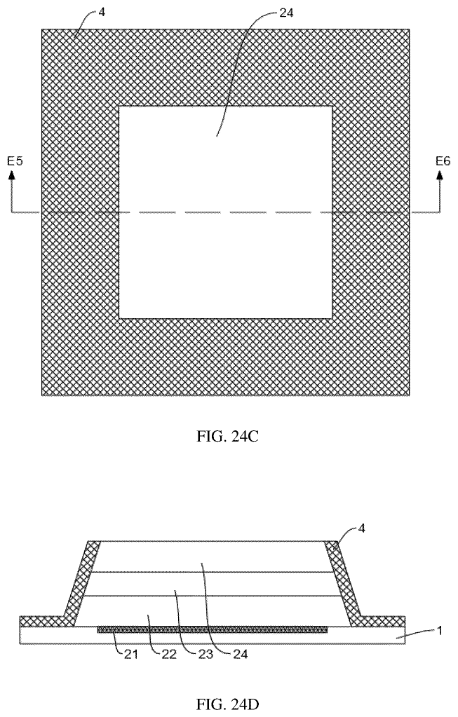

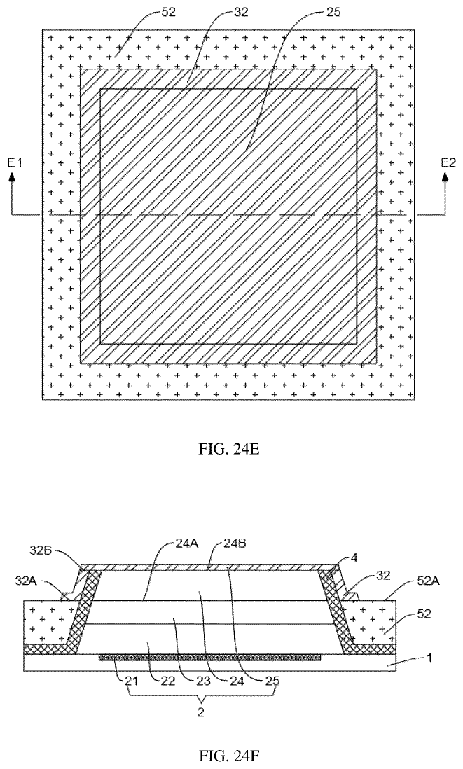

FIG. 24A to FIG. 24F show formation process diagrams of a light emitting chip provided by at least one embodiment of the present disclosure.

As shown in FIG. 24A and the schematic sectional view at position E3-E4 of FIG. 24A shown in FIG. 24B, a base substrate 1 is provided, and the base substrate 1 includes a first electrode 21 and a first connection terminal 11. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

As shown in FIG. 24C and the schematic sectional view at position E5-E6 of FIG. 24C shown in FIG. 24D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24.

As shown in FIG. 24E and the schematic sectional view at position E1-E2 of FIG. 24E shown in FIG. 24F, an organic insulation adhesive layer is formed, and the organic insulation adhesive layer is patterned to obtain a second filling layer 52. The second filling layer 52 surrounds a periphery of the first semiconductor layer 22 and a periphery of the light emitting layer 23. A first surface 52A of the second filling layer 52 away from the base substrate 1 is aligned with a first surface 24A of the second semiconductor layer 24 away from the base substrate 1.

A conductive film layer is then formed by deposition, and the conductive film layer is patterned to obtain a second electrode 25 and a second auxiliary electrode 32. The second electrode 25 is located on a side of the second semiconductor layer 24 away from the base substrate 1, and the second auxiliary electrode 32 is located on a side of the insulation layer 4 away from the second semiconductor layer 32. The second auxiliary electrode 32 extends from a surface of the insulation layer 4 to the first surface 52A of the second filling layer 52 away from the base substrate 1. The second electrode 25 is electrically connected to the second auxiliary electrode 32, and an outer edge of the second electrode 25 is connected to an edge of the second auxiliary electrode 32 away from the base substrate 1.

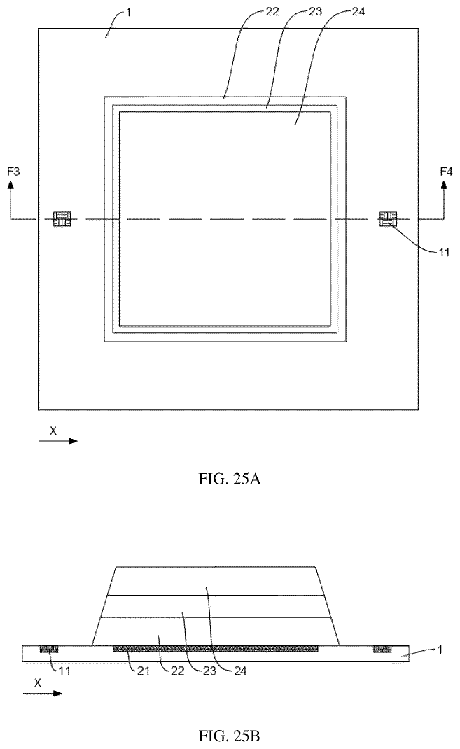

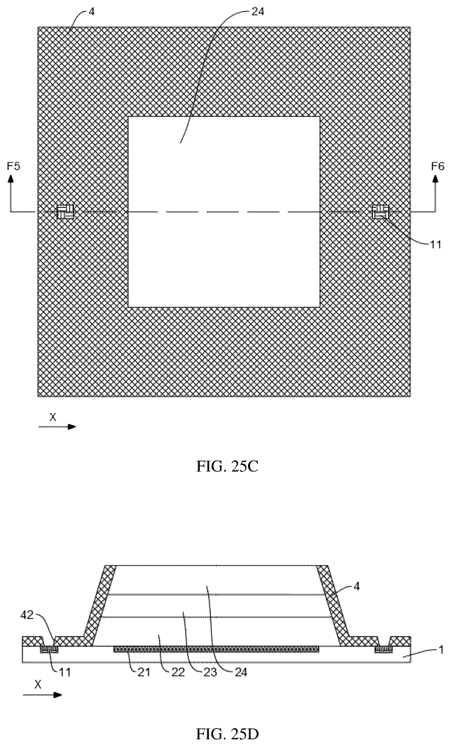

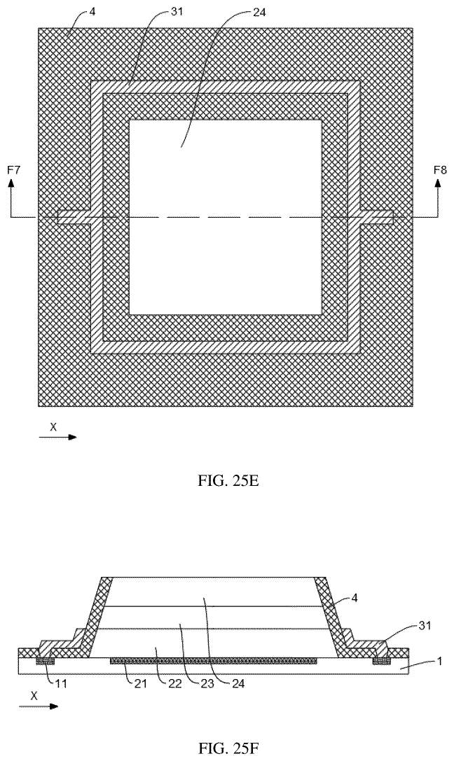

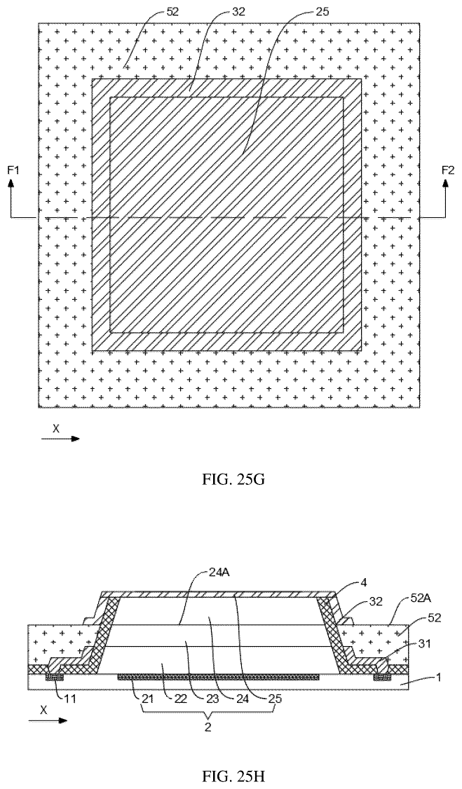

FIG. 25A to FIG. 25H show formation process diagrams of a light emitting chip provided by at least one embodiment of the present disclosure.

As shown in FIG. 25A and the schematic sectional view at position F3-F4 of FIG. 25A shown in FIG. 25B, a base substrate 1 is provided, and the base substrate 1 includes a first electrode 21. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

As shown in FIG. 25C and the schematic sectional view at position F5-F6 of FIG. 25C shown in FIG. 25D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24. Furthermore, the insulation layer 4 has a first via hole 42 exposing at least part of the first connection terminal 11.

As shown in FIG. 25E and the schematic sectional view at position F7-F8 of FIG. 25E shown in FIG. 25F, a first conductive film layer is formed by deposition, and the first conductive film layer is patterned to obtain a first auxiliary electrode 31. The first auxiliary electrode 31 is located on a side of the insulation layer 4 away from the first semiconductor layer 22, and the first auxiliary electrode 31 overlaps with the first connection terminal 11 through the first via hole 42 of the insulation layer 4.

As shown in FIG. 25G and the schematic sectional view at position F1-F2 of FIG. 25G shown in FIG. 25H, an organic insulation adhesive layer is formed, and the organic insulation adhesive layer is patterned to obtain a second filling layer 52. The second filling layer 52 surrounds a periphery of the first semiconductor layer 22 and a periphery of the light emitting layer 23. A first surface 52A of the second filling layer 52 away from the base substrate 1 is aligned with a first surface 24A of the second semiconductor layer 24 away from the base substrate 1.

A second conductive film layer is then formed by deposition, and the second conductive film layer is patterned to obtain a second electrode 25 and a second auxiliary electrode 32. The second electrode 25 is located on a side of the second semiconductor layer 24 away from the base substrate 1, and the second auxiliary electrode 32 is located on a side of the insulation layer 4 away from the second semiconductor layer 24. The second auxiliary electrode 32 extends from a surface of the insulation layer 4 to a first surface 52A of the second filling layer 52 away from the base substrate 1. The second electrode 25 is electrically connected to the second auxiliary electrode 32, and an outer edge of the second electrode 25 is connected to an edge of the second auxiliary electrode 32 away from the base substrate 1.

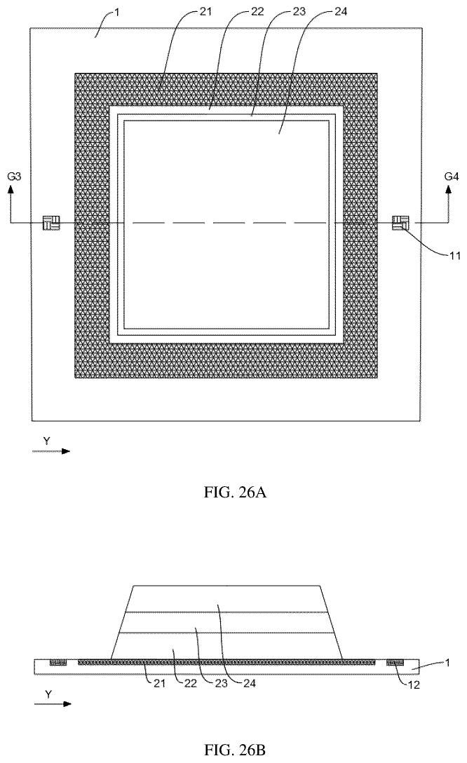

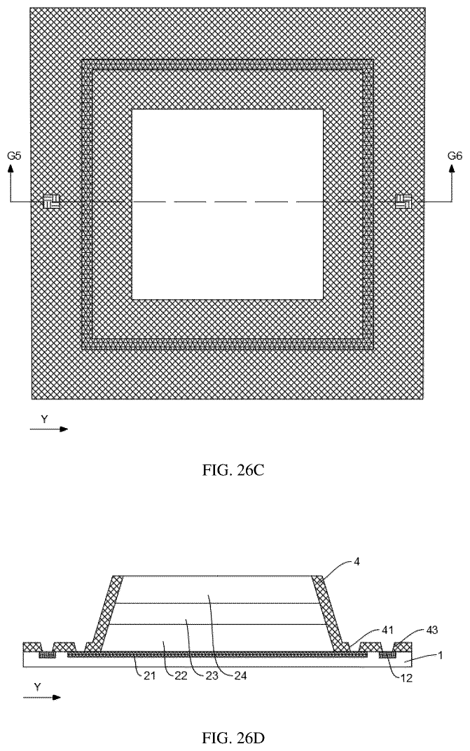

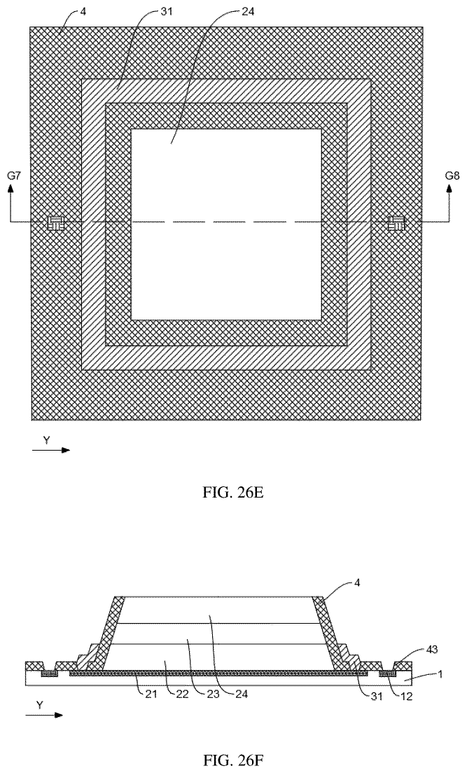

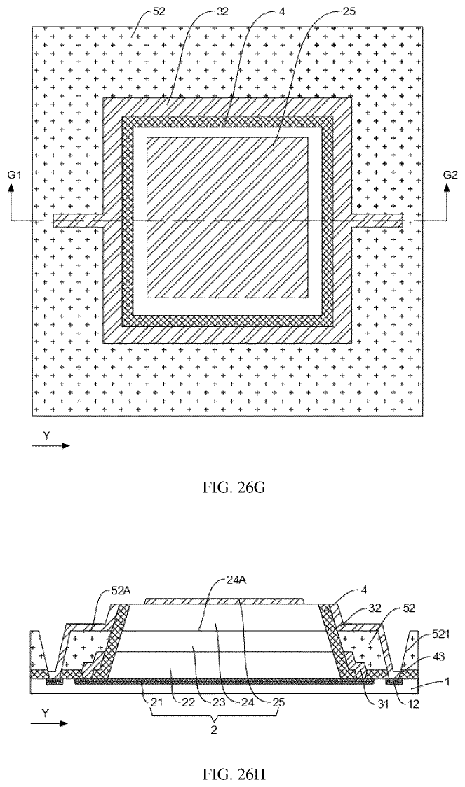

FIG. 26A to FIG. 26H show formation process diagrams of a light emitting chip provided by at least one embodiment of the present disclosure.

As shown in FIG. 26A and the schematic sectional view at position G3-G4 of FIG. 26A shown in FIG. 26B, a base substrate 1 is provided, and the base substrate 1 includes a first electrode 21 and a second connection terminal 12. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

For example, the base substrate 1 includes two second terminals 12 respectively located on two sides of the first semiconductor layer 22 in the second direction Y.

As shown in FIG. 26C and the schematic sectional view at position G5-G6 of FIG. 26C shown in FIG. 26D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24. Furthermore, the insulation layer 4 has a hollow structure 42 exposing at least part of the first electrode 21 and a second via hole 43 exposing at least part of the second connection terminal 12.

As shown in FIG. 26E and the schematic sectional view at position G7-G8 of FIG. 26E shown in FIG. 26F, a first conductive film layer is formed by deposition, and the first conductive film layer is patterned to obtain a first auxiliary electrode 31. The first auxiliary electrode 31 is located on a side of the insulation layer 4 away from the first semiconductor layer 22, and the first auxiliary electrode 31 overlaps with the first electrode 21 through the hollow structure of the insulation layer 4.

As shown in FIG. 26G and the schematic sectional view at position G1-G2 of FIG. 26G shown in FIG. 26H, an organic insulation adhesive layer is formed, and the organic insulation adhesive layer is patterned to obtain a second filling layer 52. The second filling layer 52 surrounds a periphery of the first semiconductor layer 22 and a periphery of the light emitting layer 23. A first surface 52A of the second filling layer 52 away from the base substrate 1 is aligned with a first surface 24A of the second semiconductor layer 24 away from the base substrate 1. The second filling layer has a third via hole 521, which is connected to the second via hole 43 and exposes at least part of the second connection terminal 12.

A second conductive film layer is then formed by deposition, and the second conductive film layer is patterned to obtain a second electrode 25 and a second auxiliary electrode 32. The second electrode 25 is located on a side of the second semiconductor layer 24 away from the base substrate 1, and an orthographic projection of the second electrode 25 on the base substrate 1 falls within an orthographic projection of the second semiconductor layer 24 on the base substrate 1. The second auxiliary electrode 32 is located on a side of the insulation layer 4 away from the second semiconductor layer 24. The second auxiliary electrode 32 extends from an upper surface of the second filling layer 52 to the second connection terminal 12 through a hole wall of the third via hole 521 and the second via hole 43, so as to overlap with the second connection terminal 12 to achieve an electrical connection.

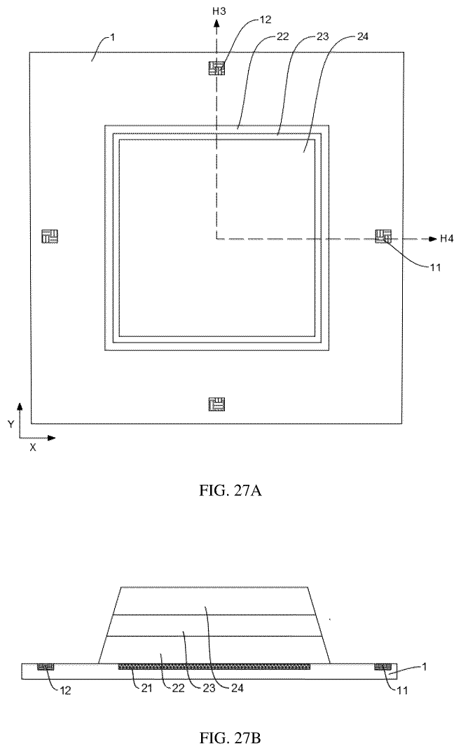

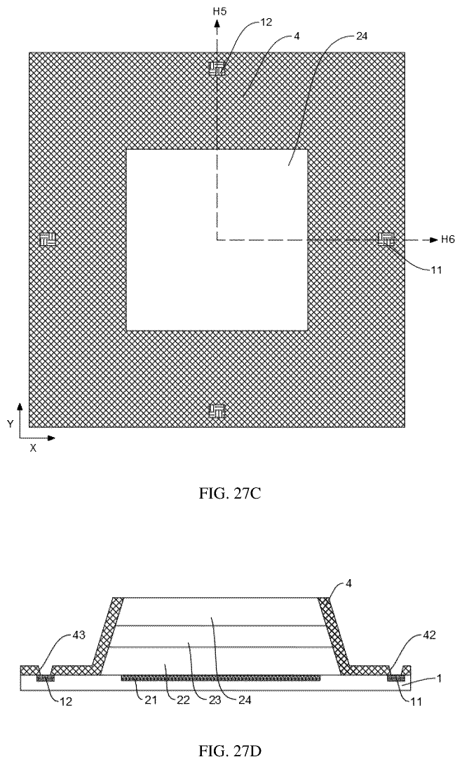

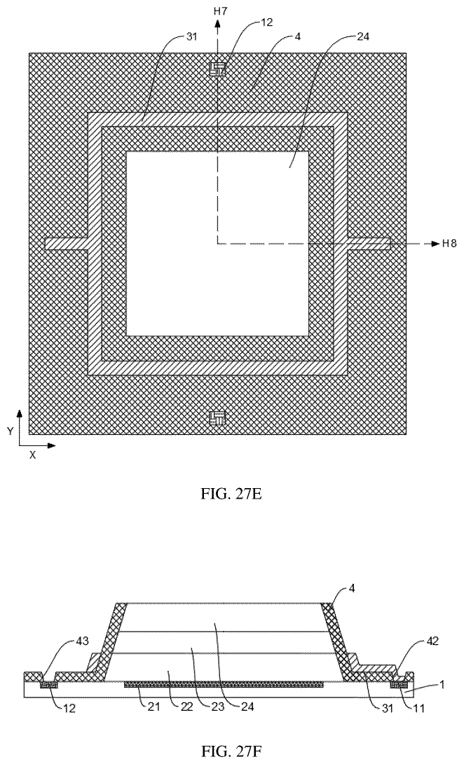

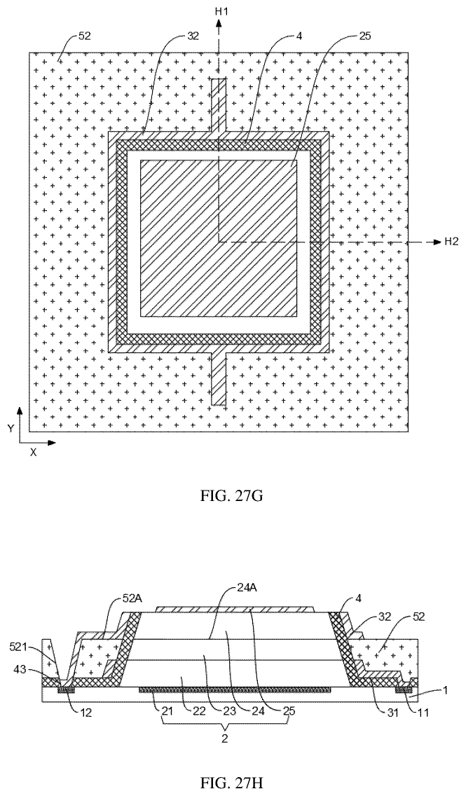

FIG. 27A to FIG. 27H show formation process diagrams of a light emitting chip provided by at least one embodiment of the present disclosure.

As shown in FIG. 27A and the schematic sectional view at position H3-H4 of FIG. 26A shown in FIG. 27B, a base substrate 1 is provided, and the base substrate 1 includes a first electrode 21, a first connection terminal 11, and a second connection terminal 12. A first semiconductor layer 22, a light emitting layer 23 and a second semiconductor layer 24 arranged in a stack are transferred onto the base substrate 1. Specifically, the first semiconductor layer 22 is transferred onto the first electrode 21 in alignment.

For example, the base substrate 1 includes two first connection terminals 11 respectively located on two sides of the first semiconductor layer 22 in the first direction X.

For example, the base substrate 1 includes two second connection terminals 12 respectively located on two sides of the first semiconductor layer 22 in the second direction Y.

For example, the first direction X is perpendicular to the second direction Y.

As shown in FIG. 27C and the schematic sectional view at position H5-H6 of FIG. 27C shown in FIG. 27D, an insulation film layer is formed by deposition, and the insulation film layer is patterned to obtain an insulation layer 4. The insulation layer 4 completely covers a sidewall of the first semiconductor layer 22, a sidewall of the light emitting layer 23 and a sidewall of the second semiconductor layer 24, and has an opening exposing the second semiconductor layer 24. Furthermore, the insulation layer 4 has a first via hole 42 exposing at least part of the first connection terminal 11 and a second via hole 43 exposing at least part of the second connection terminal 12.

As shown in FIG. 27E and the schematic sectional view at position H7-H8 of FIG. 27E shown in FIG. 27F, a first conductive film layer is formed by deposition, and the first conductive film layer is patterned to obtain a first auxiliary electrode 31. The first auxiliary electrode 31 is located on a side of the insulation layer 4 away from the first semiconductor layer 22, and the first auxiliary electrode 31 overlaps with the first connection terminal 11 through the first via hole 42 of the insulation layer 4.

As shown in FIG. 27G and the schematic sectional view at position H1-H2 of FIG. 27G shown in FIG. 27H, an organic insulation adhesive layer is formed, and the organic insulation adhesive layer is patterned to obtain a second filling layer 52. The second filling layer 52 surrounds a periphery of the first semiconductor layer 22 and a periphery of the light emitting layer 23. A first surface 52A of the second filling layer 52 away from the base substrate 1 is aligned with a first surface 24A of the second semiconductor layer 24 close to the base substrate 1. The second filling layer has a third via hole 521, which is connected to the second via hole 43 and exposes at least part of the second connection terminal 12.

A second conductive film layer is then formed by deposition, and the second conductive film layer is patterned to obtain a second electrode 25 and a second auxiliary electrode 32. The second electrode 25 is located on a side of the second semiconductor layer 24 away from the base substrate 1, and an orthographic projection of the second electrode 25 on the base substrate 1 falls within an orthographic projection of the second semiconductor layer 24 on the base substrate 1. The second auxiliary electrode 32 is located on a side of the insulation layer 4 away from the second semiconductor layer 24. The second auxiliary electrode 32 extends from an upper surface of the second filling layer 52 to the second connection terminal 12 through a hole wall of the third via hole 521 and the second via hole 43, so as to overlap with the second connection terminal 12 to achieve an electrical connection.

The embodiments of the present disclosure further provide a display panel including the light emitting chip described above. For example, the display panel may include a plurality of light emitting chips arranged in an array.

The embodiments of the present disclosure further provide a display device including the display panel described above. For example, the display device may be an electronic product having a display function, such as a television, a display, an electronic picture frame, an electronic photo frame, a navigator, a laptop computer, a tablet computer, or a smartphone.

It should be understood that the display panel and the display device according to some exemplary embodiments of the present disclosure have all the features and advantages of the light emitting chip described above, and these features and advantages may be referred to the above description of the light emitting chip, which will not be repeated here.

Herein, the terms “substantially”, “about”, “approximately” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “about” or “approximately” used herein includes a stated value and means that a specific value determined by those ordinary skilled in the art is within an acceptable range of deviation. For example, “about” may mean being within one or more standard deviations, or within ±10% or ±5% of the stated value.

Some embodiments of the general inventive concept of the present disclosure have been illustrated and described. However, those ordinary skilled in the art may understand that changes may be made to these embodiments without departing from the principle and spirit of the general inventive concept of the present disclosure, and the scope of the present disclosure is defined by the claims and their equivalents.

1. A light emitting chip, comprising
a base substrate;
a chip body provided on the base substrate, wherein the chip body comprises:
a first electrode provided on the base substrate,
a first semiconductor layer provided on a side of the first electrode away from the base substrate,
a light emitting layer provided on a side of the first semiconductor layer away from the base substrate,
a second semiconductor layer provided on a side of the light emitting layer away from the base substrate, and
a second electrode provided on a side of the second semiconductor layer away from the base substrate; and
an auxiliary electrode, comprising a first auxiliary electrode and/or a second auxiliary electrode,
wherein the first auxiliary electrode is provided to at least partially surround a periphery of a sidewall of the first semiconductor layer, the first auxiliary electrode is insulated from the first semiconductor layer, and the first auxiliary electrode is configured to be connected to a first predetermined voltage; and/or
wherein the second auxiliary electrode is provided to at least partially surround a periphery of a sidewall of the second semiconductor layer, the second auxiliary electrode is insulated from the second semiconductor layer, and the second auxiliary electrode is configured to be connected to a second predetermined voltage.

2. The light emitting chip according to claim 1, wherein the light emitting chip further comprises an insulation layer provided on the sidewall of the first semiconductor layer, a sidewall of the light emitting layer and the sidewall of the second semiconductor layer, and
the first auxiliary electrode is provided on a surface of the insulation layer away from the first semiconductor layer; and/or
at least part of the second auxiliary electrode is provided on a surface of the insulation layer away from the second semiconductor layer.

3. The light emitting chip according to claim 2,
wherein the first auxiliary electrode is provided to continuously surround a surface of the insulation layer; and/or
wherein at least part of the second auxiliary electrode is provided to continuously surround the surface of the insulation layer.

4. The light emitting chip according to claim 2,
wherein a first surface of the first auxiliary electrode close to the base substrate is aligned with a first surface of the first semiconductor layer close to the base substrate; and a second surface of the first auxiliary electrode away from the base substrate is aligned with a second surface of the first semiconductor layer away from the base substrate; and/or
wherein a first surface of the second auxiliary electrode close to the base substrate is aligned with a first surface of the second semiconductor layer close to the base substrate, or the first surface of the second auxiliary electrode close to the base substrate is closer to the base substrate than the first surface of the second semiconductor layer close to the base substrate; and a second surface of the second auxiliary electrode away from the base substrate is aligned with a second surface of the second semiconductor layer away from the base substrate.

5. The light emitting chip according to claim 2,
wherein a material of the first auxiliary electrode is selected from a conductive metal oxide material or a metal material; and/or
wherein a material of the second auxiliary electrode is selected from a conductive metal oxide material or a metal material.

6. The light emitting chip according to claim 2, wherein the first auxiliary electrode is electrically connected to the first electrode, and the first electrode and the first auxiliary electrode are connected to the same first predetermined voltage.

7. The light emitting chip according to claim 6, wherein the second electrode is located in the same layer as the first auxiliary electrode.

8. The light emitting chip according to claim 2, wherein the base substrate further comprises a first connection terminal, the first auxiliary electrode is electrically connected to the first connection terminal, and the first connection terminal is configured to provide the first predetermined voltage to the first auxiliary electrode.

9. The light emitting chip according to claim 8, wherein the base substrate comprises at least two first connection terminals respectively located on two sides of the chip body in a first direction, and the first auxiliary electrode is electrically connected to the at least two first connection terminals, respectively.

10. The light emitting chip according to claim 8, wherein an orthographic projection of the first electrode on the base substrate falls within an orthographic projection of the first semiconductor layer on the base substrate.

11. The light emitting chip according to claim 2, wherein the light emitting chip further comprises a first filling layer, the first filling layer covers the insulation layer and the first auxiliary electrode, and a first surface of the first filling layer away from the base substrate is aligned with a second surface of the second semiconductor layer away from the base substrate.

12. The light emitting chip according to claim 2, wherein the light emitting chip further comprises a second filling layer surrounding a periphery of the chip body, a first surface of the second filling layer away from the base substrate is aligned with a first surface of the second semiconductor layer close to the base substrate, and the second auxiliary electrode extends from a surface of the insulation layer to a first surface of the second filling layer away from the base substrate.

13. The light emitting chip according to claim 12, wherein the second auxiliary electrode is electrically connected to the second electrode, and the second electrode and the second auxiliary electrode are connected to the same second predetermined voltage.

14. The light emitting chip according to claim 13, wherein the second auxiliary electrode is located in the same layer as the second electrode.

15. The light emitting chip according to claim 12, wherein the base substrate further comprises a second connection terminal, the second auxiliary electrode is electrically connected to the second connection terminal, and the second connection terminal is configured to provide a second predetermined voltage to the second auxiliary electrode.

16. The light emitting chip according to claim 15, wherein the base substrate comprises at least two second connection terminals respectively located on two sides of the chip body in a second direction, and the second auxiliary electrode is electrically connected to the at least two second connection terminals, respectively.

17. The light emitting chip according to claim 15, wherein the second filling layer comprises a via hole exposing at least part of the second connection terminal, and the second auxiliary electrode overlaps with the second connection terminal through the via hole;
wherein in a direction from a center of the chip body to an outside, a distance between a sidewall of the second filling layer close to the chip body and a sidewall of the via hole close to the chip body is greater than a size of the insulation layer,
wherein an orthographic projection of the second electrode on the base substrate falls within an orthographic projection of the second semiconductor layer on the base substrate,
wherein the first semiconductor layer is an N-type semiconductor layer, and the first predetermined voltage is a negative voltage; and/or
wherein the second semiconductor layer is a P-type semiconductor layer, and the second predetermined voltage is a positive voltage.

18-20. (canceled)

21. A method of manufacturing a light emitting chip, comprising:
providing a base substrate;
forming a chip body on the base substrate, wherein the chip body comprises: a first electrode formed on the base substrate, a first semiconductor layer formed on a side of the first electrode away from the base substrate, a light emitting layer formed on a side of the first semiconductor layer away from the base substrate, a second semiconductor layer formed on a side of the light emitting layer away from the base substrate, and a second electrode formed on a side of the second semiconductor layer away from the base substrate; and
forming an auxiliary electrode, wherein the auxiliary electrode comprises a first auxiliary electrode and/or a second auxiliary electrode,
wherein the first auxiliary electrode is provided to at least partially surround a periphery of a sidewall of the first semiconductor layer, the first auxiliary electrode is insulated from the first semiconductor layer, and the first auxiliary electrode is configured to be connected to a first predetermined voltage; and/or
wherein the second auxiliary electrode is provided to at least partially surround a periphery of a sidewall of the second semiconductor layer, the second auxiliary electrode is insulated from the second semiconductor layer, and the second auxiliary electrode is configured to be connected to a second predetermined voltage.

22. A display panel, comprising the light emitting chip according to claim 1.

23. A display device, comprising the display panel according to claim 22.
